(19) United States
(12) Patent Application Publication
(10) Pub. No.: US 2013/0020679 A1
(43) Pub. Date: Jan. 24, 2013

(54) SEMICONDUCTOR DEVICE AND PRODUCTION METHOD THEREOF

(71) Applicant: Kouichi Nagai, Kuwana (JP)

(72) Inventor: Kouichi Nagai, Kuwana (JP)

(73) Assignee: FUJITSU SEMICONDUCTOR LIMITED, Yokohama-shi (JP)

(21) Appl. No.: 13/444,436

(22) Filed: Apr. 11, 2012

(30) Foreign Application Priority Data
Jul. 20, 2011 (JP) 2011-159321

(51) Int. Cl. H01L 27/08; H01L 21/02

(52) U.S. Cl. 257/532; 438/3; 257/E21.008; 257/E27.048

(57) ABSTRACT

When producing ferroelectric memory devices on a wafer, a memory cell expected to provide the severest degradation of fatigue characteristics is selected from a chip region of the wafer in which the fatigue characteristics are expected to be the poorest, based on the knowledge acquired in advance with regard to the in-plane distribution of the fatigue characteristics on a wafer. The predetermined number of times of rewriting data is guaranteed by conducting fatigue test in the memory cell thus selected for all of the wafers such that, when the result of the fatigue test is good, the entire devices on the wafer are rendered good with regard to the fatigue characteristics.

### CROSS-REFERENCE TO RELATED APPLICATIONS

This application is based upon and claims the benefit of priority of the prior Japanese Patent Application 2011-159321, filed on Jul. 20, 2011, the entire contents of which are hereby incorporated by reference.

### FIELD

The embodiments described herein relate to a a semiconductor device having a ferroelectric capacitor and production method thereof.

### BACKGROUND

A semiconductor device having a ferroelectric capacitor, such as a ferroelectric memory device, is a high-speed non-volatile memory device operating with low power consumption and is used in various fields.

### PRIOR ART REFERENCES

### Patent References

Patent Reference 1 Japanese Laid-Open Patent Application 2008-177389

### SUMMARY

In an aspect, there is provided a method of producing semiconductor devices, comprising: a first step of acquiring an in-plane distribution of fatigue characteristics for ferroelectric capacitors formed on a testing wafer; and a second step of fabricating semiconductor devices having respective ferroelectric capacitors on a wafer as a product based on said in-plane distribution, wherein said second step comprises: forming said plurality of ferroelectric capacitors on said wafer on which said semiconductor devices are fabricated as a product; designating a specific region of said wafer on which said semiconductor devices are fabricated as a product from said in-plane distribution of fatigue characteristics acquired in said first step; measuring fatigue characteristics of a ferroelectric capacitor of a semiconductor device on said specific region; judging said ferroelectric capacitor of said specific region as to good or fail based on said fatigue characteristics measured for said ferroelectric capacitor of said semiconductor device on said specific region; and rendering that all of said plurality of ferroelectric capacitors are good on said wafer on which said semiconductor devices are fabricated as a product when a result of said judging is good.

Additional objects and advantages of the embodiments will be set forth in part in the description which follows, and in part will be obvious from the description, or may be learned by practice of the disclosures. The object and advantages of the disclosures will be realized and attained by means of the elements and combinations particularly pointed out in the appended claims.

It is to be understood that both the foregoing general description and the following detailed description are exemplary and explanatory only and are not restrictive of the disclosures, as claimed.

### BRIEF DESCRIPTION OF DRAWINGS

FIG. 1 is a schematic plan-view diagram representing a silicon wafer used in a first embodiment;

FIG. 2A is a cross-sectional diagram representing a cell of a planar ferroelectric memory device used in the first embodiment;

FIG. 2B is a cross-sectional diagram representing a cell of a stacked-type ferroelectric memory device used in the first embodiment;

FIG. 3 is a block diagram representing a schematic construction of a testing apparatus according to the first embodiment;

FIG. 4A is a flowchart representing a summary of the test conducted by the testing apparatus of FIG. 3;

FIG. 4B is a flowchart representing an example of the process of the present embodiment for acquiring the information used in the flowchart of FIG. 4A;

FIG. 4C is a flowchart representing a modification FIG. 4B;

FIG. 5 is a cross-sectional diagram representing the construction of a semiconductor integrated circuit device according to a second embodiment;

FIG. 6A is a plan view diagram representing the overall memory cell array used with the semiconductor integrated circuit device of FIG. 5;

FIG. 6B is a diagram representing a part of FIG. 6A with enlarged scale;

FIG. 7 is a cross-sectional diagram taken along a line A-A′ of FIG. 6B;

FIG. 8 is a schematic diagram showing the construction of the manufacturing apparatus according to the fourteenth embodiment;

FIG. 9 is a cross-sectional diagram representing, the construction of a semiconductor integrated circuit device according to a third embodiment;

FIG. 10 is a plan view diagram representing the overall memory cell array used with the semiconductor integrated circuit device of FIG. 9;

FIG. 11 is a cross-sectional diagram representing a cross-section of FIG. 10;

FIG. 12 is another plan view diagram representing a memory cell array used with the semiconductor integrated circuit device of FIG. 9;

FIG. 13 is a flowchart representing an outline of the test conducted with the fourteenth embodiment;

FIG. 14A is a plan view diagram representing a part of a memory cell array in a semiconductor integrated circuit device that uses a planar-ferroelectric memory device;

FIG. 14B is a plan view diagram representing a modification of the embodiment of FIG. 14A; and

FIG. 15 is a plan view diagram representing a part of the memory cell array in a semiconductor integrated circuit device that uses a planar-ferroelectric memory device;

### DESCRIPTION OF EMBODIMENT

In the semiconductor devices having a ferroelectric capacitor, such as non-volatile ferroelectric memory devices, it is generally necessary to conduct a fatigue test, in addition to the operational test for an ordinary semiconductor device, in order to guarantee a predetermined number of times for rewriting of data. Such a test may be conducted by conducting writing and reading of data repeatedly at the temperature condition of 90° C., for example. The semiconductor device is shipped to the customers only after such fatigue test is conducted.

In the case of ferroelectric memory device, this guaranteed number of rewriting may be 1×10¹⁰ or more, and thus, a very long time is needed for conducting such a fatigue test. It is therefore not practical to conduct such a fatigue test on all of the chips on a wafer or on all of the semiconductor devices. Further, in the fatigue test, the test is conducted by writing and reading of data, and thus, it is harmful to conduct such a fatigue test to all of the semiconductor devices on the wafer, and hence to the memory cells which are actually shipped as product.

Thus, it has been practiced in the art to sample a small number of wafers in each production lot and test the fatigue characteristics by using monitoring patterns that are provided in several locations, such as five locations, on the wafer. For such a monitoring pattern, it is general to use ferroelectric capacitors formed on a scribe line of a wafer by a process similar to that of the ferroelectric capacitor of the product semiconductor device. When a defect is detected in such monitoring, the entire wafers of that lot are discarded.

On the other hand, it has been found recently that it is not possible to completely reject the chips having defects in the fatigue characteristics by using such an indirect fatigue test process, which relies upon the use of the monitoring patterns. This means that there are cases in which the ferroelectric capacitors for monitoring do not always represent the characteristics of the ferroelectric capacitor of the product semiconductor devices.

### First Embodiment

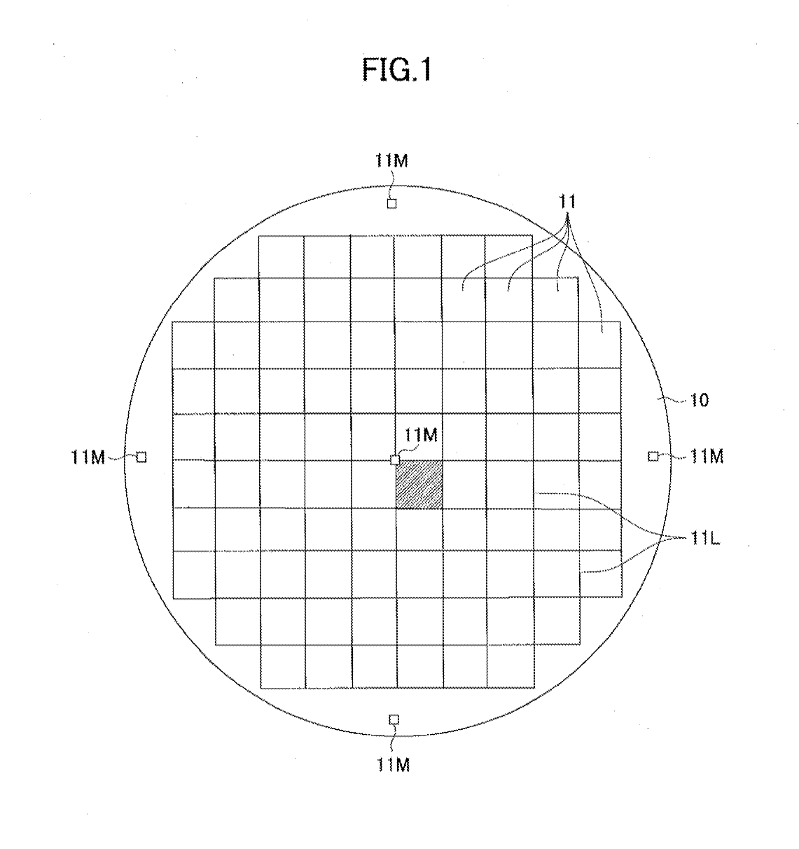

FIG. 1 is a schematic plan view diagram representing a silicon wafer used in a first embodiment.

Referring to FIG. 1, the silicon wafer 10 is defined with a large number of chip regions 11 respectively corresponding to semiconductor chips, wherein each chip region 11 is formed with a semiconductor device having a ferroelectric capacitor such as a ferroelectric memory device. The silicon wafer 10 thus formed is diced, after the fabrication process is finished, into individual semiconductor chips along scribe lines 11L separating a chip region 11 from an adjacent chip region.

Further, on the silicon wafer 10, there are provided monitoring patterns 11M for testing the characteristics of the ferroelectric capacitors formed on the silicon wafer at several locations, five in the illustrated example, on the scribe lines 11L, or the like, for avoiding the chip region 11. These monitoring patterns 11M are actually the ferroelectric capacitors isolated from each other and are formed by the same process to have the same structure of the ferroelectric capacitors formed on the chip regions 11. The monitoring patterns 11M are used for testing such properties. It should be noted, however, that the monitoring patterns 11M are not the actual ferroelectric capacitor constituting the memory cells in the chip region 11, and thus, the test conducted by using the monitoring pattern 11M becomes inevitably an indirect test.

As noted previously, it is required, in the semiconductor devices having a ferroelectric capacitor such as a ferroelectric memory device, to test and guarantee the fatigue characteristics of the ferroelectric capacitors after fabrication of the semiconductor device, in addition to conducting ordinary operational test. In the fatigue test of ferroelectric capacitors, it is necessary to repeat the process of reading and wiring data to and from the ferroelectric capacitor up to a predetermined, guaranteed number of times.

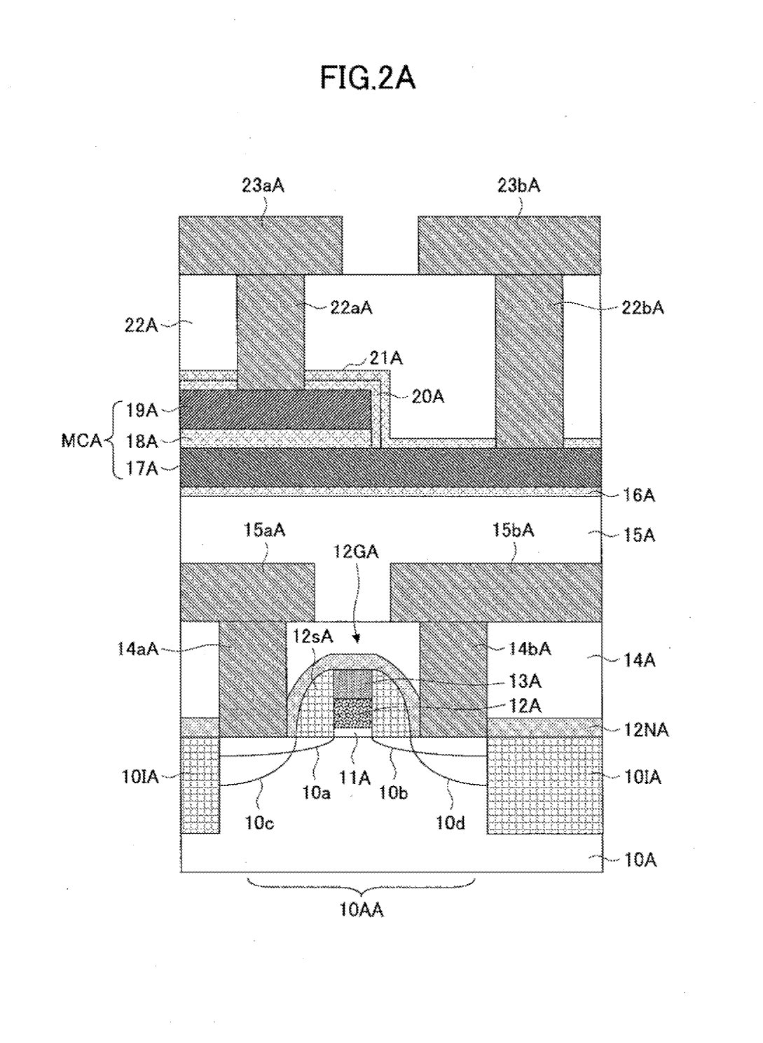

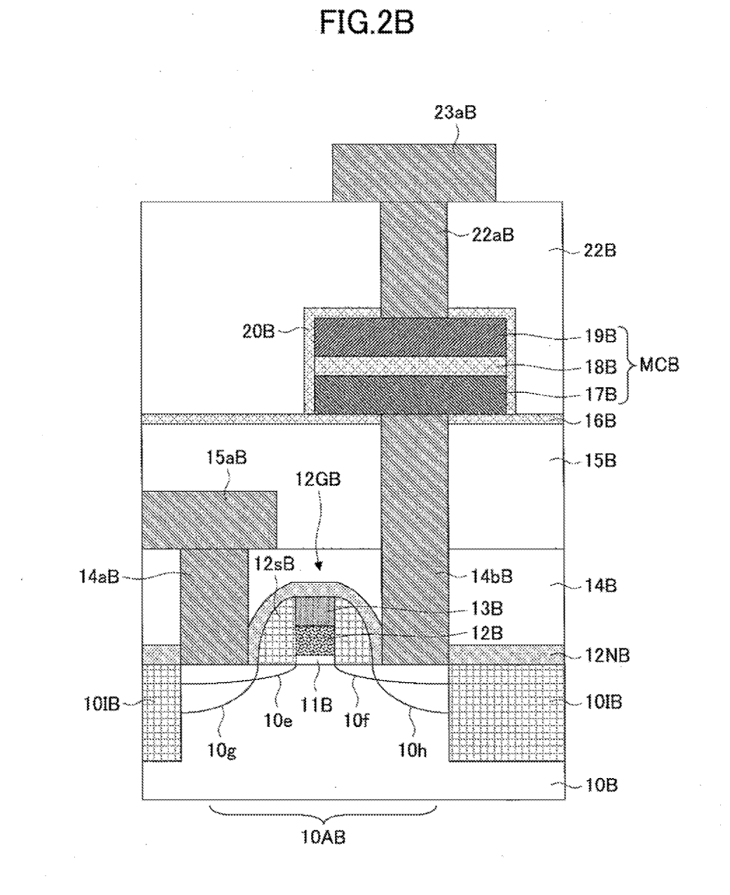

FIG. 2A represents an example of a semiconductor device 10A formed on the silicon wafer 10 while FIG. 2B is a cross-sectional diagram representing an example of a semiconductor device 10B formed on the silicon wafer 10.

Referring to FIG. 2A, the semiconductor device 10A is a planar-type ferroelectric memory device and FIG. 2A represents only one memory cell thereof.

More specifically, there is defined a device region 10AA on the silicon wafer 10, or on a silicon substrate 10A corresponding to a silicon wafer 60 to be explained later, by a device isolation region 101A for a memory cell transistor, and a gate electrode pattern 12GA of so-called polycide structure is formed on the device region 10AA by stacking consecutively a silicon pattern 12A of amorphous or polysilicon and a silicide pattern 13A over a gate insulation film 11A. Further, sidewall insulation films 12sA are formed on the mutually opposing sidewall surfaces of the gate electrode pattern 13GA.

In the silicon substrate 10A, there are formed a source extension region 10a and a drain extension region 10b respectively in correspondence to the mutually opposing sidewall surfaces of the gate electrode pattern 12GA by an ion implantation process of an impurity element to have a conductivity type opposite to the conductivity type of the silicon substrate 10A, and there are formed a source region 10c and a drain region 10d in the silicon substrate 10A at an outer side of the sidewall insulation films 12sA as viewed from a channel region right underneath the gate electrode 12GA by an ion implantation process of an impurity element to have the conductivity type identical to the conductivity type of the source extension region 10a and the drain extension region 10b.

In an example, the gate insulation film may be formed of a thermal oxide film having a film thickness of 6 nm-7 nm, a silicon pattern 12A constituting the gate electrode 12GA may have a film thickness of 50 nm, the silicide pattern 13A may be formed of WSi and may have a film thickness of 150 nm, and the gate electrode 12GA may have a width of 360 nm. ⱼ In this case, the memory cell transistor of FIG. 2A has a gate length of 360 nm. Further, the sidewall insulation films 12sA may have a film thickness of 45 nm, and an SiON film 12NA having a film thickness of 20 nm-30 nm is provided thereon. Further, the device region 10AA is doped by B to p-type, and the source extension region 10a and the drain extension region 10b are doped to n-type by P. Further, the source region 10c and the drain region 10d are doped to n+-type by As. It should be noted, however, that the memory cell transistor of FIG. 2A is not limited to those explained above.

The gate electrode 12GA is covered, together with the sidewall insulation films 12sA, by an interlayer insulation film 14A via an oxygen barrier film 12NA of SiON or SiN formed on the silicon substrate 10A, wherein the interlayer insulation film 14A is formed with a via-plug 14aA making electric contact with the source region 10c and a via-plug 14bA making electric contact with the drain region 10d.

Further, on the interlayer insulation film 14, there are formed interconnection patterns 15aA and 15bA respectively in electric contact with the via-plugs 14aA and 14bA, wherein a next interlayer insulation film 15A is formed over the interlayer insulation film 14A so as to cover the interconnection patterns 15aA and 15bA.

On the interlayer insulation film 15A, there is formed an Al₂O₃ film 16A having a film thickness of 20 nm, for example, for a hydrogen barrier film, and there is formed a ferroelectric capacitor (memory cell capacitor) MCA on the Al₂O₃ film 16A by consecutively stacking a lower electrode 17A of a Pt film or the like, a ferroelectric film 18A of a PZT film of (111) alignment, and further an upper electrode 19A of an IrO₂ film 18A by a sputtering process with the respective film thicknesses of 150 nm, 140 nm and 250 nm. Further, the part of the stacked structure formed of the ferroelectric film 18A and the upper electrode 19A is covered by another hydrogen barrier film 20A of an Al₂O₃ film having the film thickness of 50 nm, and the entirety of the ferroelectric capacitor MCA including the lower electrode 17A is covered by another hydrogen barrier film 21A of an Al₂O3 film having a film thickness of 20 nm. The hydrogen barrier films 16A, 20A and 21A works to block the penetration of hydrogen into the ferroelectric capacitor MCA and reduction of the ferroelectric film 18A during the fabrication process of the semiconductor device.

Further, the Pt film constituting the lower electrode 17A exhibit strong (111) orientation and functions to constraint the crystal orientation of the ferroelectric film 18A formed thereon to the (111) orientation.

Further, a next interlayer insulation film 22A is formed on the interlayer insulation film 15A, wherein a via-plug 22aA contacting with the upper electrode 19A and a via-plug 22bA contacting with the lower electrode 17A are formed in the interlayer insulation film 22A. Further, there are formed a′ first interconnection pattern 23aA and a second interconnection pattern 23bA on the interlayer insulation film 22A respectively in contact with the via-plug 22aA and the via-plug 22bA. The interconnection pattern 23bA is connected to the interconnection pattern 15bA and further to the drain region 10d of the memory cell transistor formed in the device region 10AA by another via-plug not illustrated.

With such a ferroelectric memory device, information is recorded in the ferroelectric film 18A in the form of spontaneous polarization by applying a voltage between the electrodes 17A and 19A via the memory cell transistor. Further, the information written into the ferroelectric film 18A is read out by comparing the voltage induced between the lower electrode 17A and the upper electrode 19A by the ferroelectric film 18A with a reference voltage.

Next, referring to FIG. 2B, the semiconductor device 10B is a stack-type ferroelectric memory device and FIG. 2B represents only one memory cell thereof.

More specifically, there is defined a device region 10AB on the silicon wafer 10, or on a silicon substrate 10B corresponding to a silicon wafer 60 to be explained later, by a device isolation region 101B for a memory cell transistor, and a gate electrode pattern 12GB of so-called polycide structure is formed on the device region 10AB by stacking consecutively a silicon pattern 12B of amorphous or polysilicon and a silicide pattern 13B over a gate insulation film 11B. Further, sidewall insulation films 12sB are formed on the mutually opposing sidewall surfaces of the gate electrode pattern 13GB.

In the silicon substrate 10B, there are formed a source extension region 10e and a drain extension region 10f respectively in correspondence to the mutually opposing sidewall surfaces of the gate electrode pattern 12GB by an ion implantation process of an impurity element to have a conductivity type opposite to the conductivity type of the silicon substrate 10B, and there are formed a source region 10g and a drain region 10h in the silicon substrate 10B at an outer side of the sidewall insulation films 12sB as viewed from a channel region right underneath the gate electrode 12GB by an ion implantation process of an impurity element to have the conductivity type identical to the conductivity type of the source extension region 10e and the drain extension region 10f.

In an example, the gate, insulation film may be formed of a thermal oxide film having a film thickness of 6 nm-7 nm, a silicon pattern 12B constituting the gate electrode 12GB may have a film thickness of 50 nm, the silicide pattern 13B may be formed of WSi and may have a film thickness of 150 nm, and the gate electrode 12GB may have a width of 360 nm. ⱼ In this case, the memory cell transistor of FIG. 2B has a gate length of 360 nm. Further, the sidewall insulation films 12sB may have a film thickness of 45 nm, and the SiON film 12NB may have a film thickness of 20 nm-30 nm. Further, the device region 10AB is doped by B to p-type, and the source extension region 10e and the drain extension region 10f are doped to n-type by P. Further, the source region 10g and the drain region 10h are doped to n+-type by As. It should be noted, however, that the memory cell transistor of FIG. 2B is not limited to those explained above.

On the silicon substrate 10B, it should be noted that the gate electrode 12GB is covered, together with the sidewall insulation films 12sB, with an interlayer insulation film 14B via an SiN film 12NB of the film thickness of 20 nm-30 nm acting as an oxygen barrier film, wherein the interlayer insulation film 14B is formed with a via-plug 14aB contacting with the source region 10g electrically and a via-plug 14bB contacting with the drain region 10h electrically.

Further, there is formed an interconnection pattern 15aB on the interlayer insulation film 14B in electrical contact with the via-plug 14aB, and a next interlayer insulation film 15B is formed on the interlayer insulation film 14A so as to cover the interconnection pattern 15aB.

On the interlayer insulation film 15B, there is formed an Al₂O₃ film 16B acting as a hydrogen barrier film, and a ferroelectric capacitor MCA is formed on the Al₂O₃ film 16B by consecutively stacking a lower electrode 17B of Pt, or the like, a ferroelectric film 18B of a (111) oriented PZT film or the like, and an upper electrode 19B of IrO₂ film, or the like, by a sputtering process. The ferroelectric capacitor MCA is further covered by another hydrogen barrier film 20B of Al₂O₂. The hydrogen barrier films 16B and 20BA works to block the penetration of hydrogen into the ferroelectric capacitor MCA and reduction of the ferroelectric film 18B during the fabrication process of the semiconductor device.

Further, with the ferroelectric memory device of stacked type of FIG. 2B, there is formed a via-plug 14bB through the hydrogen barrier film 16B and the interlayer insulation films 15B and 14B, wherein the lower electrode 17B is connected to the drain region 10h of the memory cell transistor formed in the device region 10AB.

Further, the Pt film constituting the lower electrode 17B exhibit strong (111) orientation and functions to constraint the crystal orientation of the ferroelectric film 18B formed thereon to the (111) orientation.

On the interlayer insulation film 15B, there is formed a next interlayer insulation film 22B, wherein the interlayer insulation film 22B is formed with a via-plug 22aB contacting with the upper electrode 19B. Further, an interconnection pattern 23aB is formed on the interlayer insulation film 22B in contact with the via-plug 22aB.

With such a ferroelectric memory device, information is recorded in the ferroelectric film 18B in the form of spontaneous polarization by applying a voltage between the electrodes 17B and 19B via the memory cell transistor. Further, the information written into the ferroelectric film 18B is read out by comparing the voltage induced between the lower electrode 17B and the upper electrode 19B by the ferroelectric film 18B with a reference voltage.

While FIGS. 2A and 2B represent the case in which one semiconductor device includes only one memory cell, they can be a semiconductor integrated circuit device in which a large number of ferroelectric memory devices each having the construction represented in FIG. 2A or 2B are integrated as will be explained later with reference to embodiments.

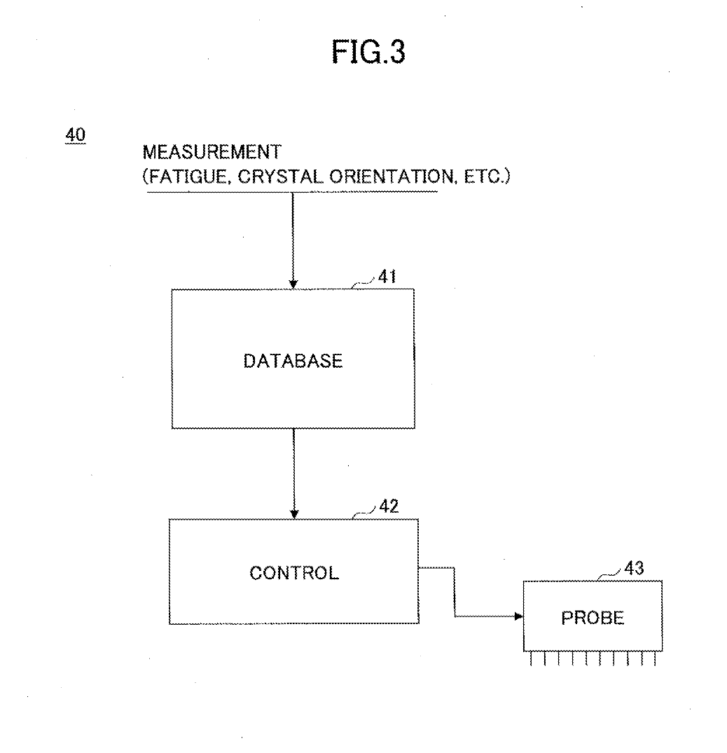

FIG. 3 is a block diagram representing the outline of a testing apparatus 40 used with the present embodiment for conducting fatigue test to a large number of devices, particularly the ferroelectric capacitors thereof, formed on such a silicon wafer 10.

Referring to FIG. 3, the testing apparatus includes a database 41, which may include a computer equipped with a data recording apparatus such as non-volatile memory or magnetic recording apparatus, wherein the database 41 is recorded with information as to the in-plane distribution that what chip area 11 of the silicon wafer 10 provides the poorest fatigue characteristics for the ferroelectric capacitor, based on the actual measurement of the fatigue characteristics for a large number of ferroelectric capacitors formed on the respective chip areas 11. In one example, such information is stored in a data recording apparatus of the foregoing computer.

In constructing such a database 41 by actually measuring the fatigue characteristics of the ferroelectric capacitors, a straightforward approach may be to select one ferroelectric capacitor for each chip region 11 on the silicon wafer 10 of FIG. 1, and carry out writing and reading of data for more than 10⁷ times, preferably more than 10¹¹ times corresponding to the guaranteed number of times. However, this approach takes enormous time.

Meanwhile, it is known that, in the case of using a (111) oriented PZT film or SBT (SrBi₂Ta₂O₉) film for the ferroelectric film of the ferroelectric capacitor, there is a correlation between the fatigue and the crystal orientation, more specifically the degree of (111) orientation or the degree of (222) orientation. For example, it is known that a PZT film having excellent fatigue characteristics has a degree of crystal orientation for the (111) orientation or (222) orientation with a proportion of 90% or more (actually 93% or more) and that a PZT film of poor fatigue characteristics have lower degree of crystal orientation with regard to the (111) orientation or (222) orientation. Here, crystal orientation means the proportion of the ferroelectric crystal grains constituting the ferroelectric film and having the (111) orientation.

Thus, by obtaining the degree of crystal orientation, and hence the degree of the (111) orientation or the (222) orientation, for the ferroelectric film over the entire chip region 11 of the silicon wafer 10 by X-ray diffraction, it is easily identify the chip region 11 where the degree of the (111) orientation or the (222) orientation is the lowest.

Here, it should be noted that, while PZT is a general designation of the compound of the perovskite structure having the chemical formula of Pb(Zr,Ti)O₃, PZT used herein also includes those compounds containing La and having the composition represented as PLZT: (Pb,La)(Zr,Ti)O₃ or the compounds further doped with Ca or Sr.

For example, it is known empirically that the degree of crystal orientation for the (111) orientation or the (222) orientation becomes the lowest in the chip region 11 located at the central part of the silicon wafer 10 as shaded in FIG. 1 in the case a PZT film is used for the ferroelectric film of the ferroelectric capacitor and the PZT film is formed by a sputtering process or sol-gel process. Further, in the case another manufacturing method such as MOCVD process is employed, it is empirically known that the degree of crystal orientation for the (111) orientation or the (222) orientation is degraded in the chip regions other than the wafer center such as the chip regions 11 located in the peripheral part in FIG. 1. Thus, the database 41 stores such information. In a practical example of the information stored in the database 41, the items such as wafer diameter, type of the ferroelectric film, manufacturing method of the ferroelectric film and the in-plane distribution of the crystal orientation or in-plane distribution of the fatigue properties, may be possible.

Thus, with the present embodiment, a control unit that controls the fatigue test based on the information stored in the database 41 designates, at the time of fabrication of the product semiconductor devices, a specific ferroelectric capacitor of a specific chip region in which the degradation of the fatigue characteristics is expected to be most significant based on the foregoing information, and a tester or a probe card 43 for the writing and reading of data is caused to make a contact with the selected ferroelectric capacitor of the selected chip region. Further, the fatigue test is conducted by repeatedly writing and reading test data for a predetermined guaranteed number of times under the temperature condition of 90° C., for example. In the present embodiment, this fatigue test is conducted for all of the wafers on which the product semiconductor devices to be shipped are formed.

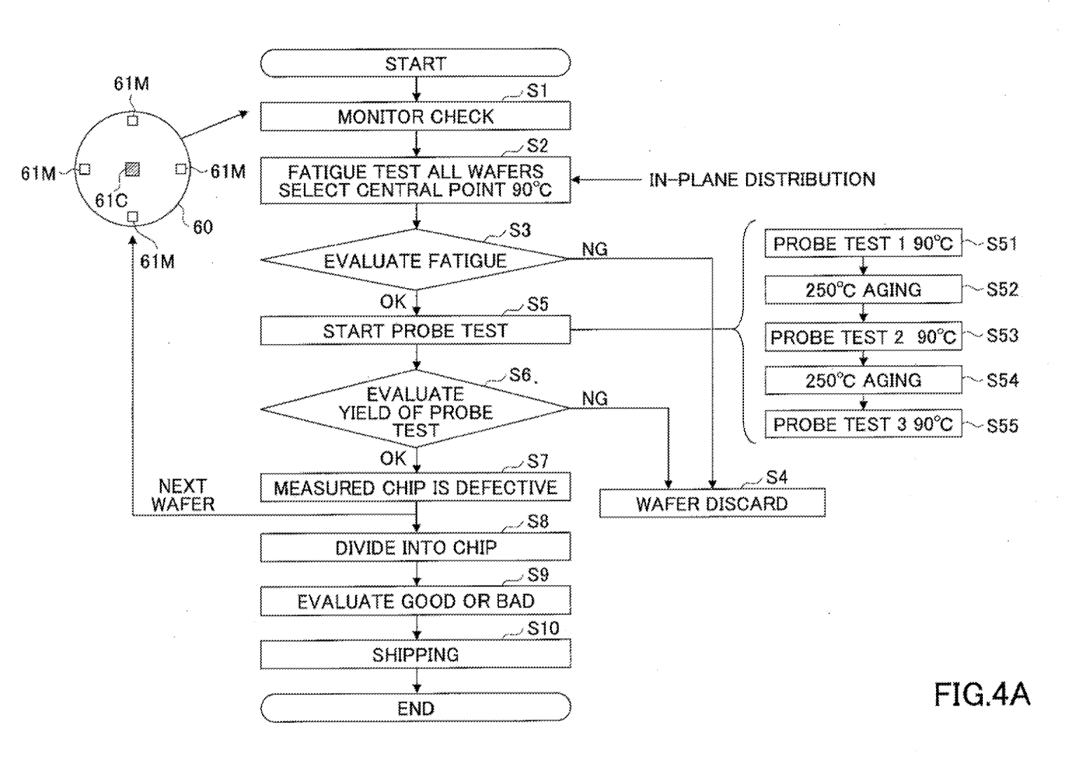

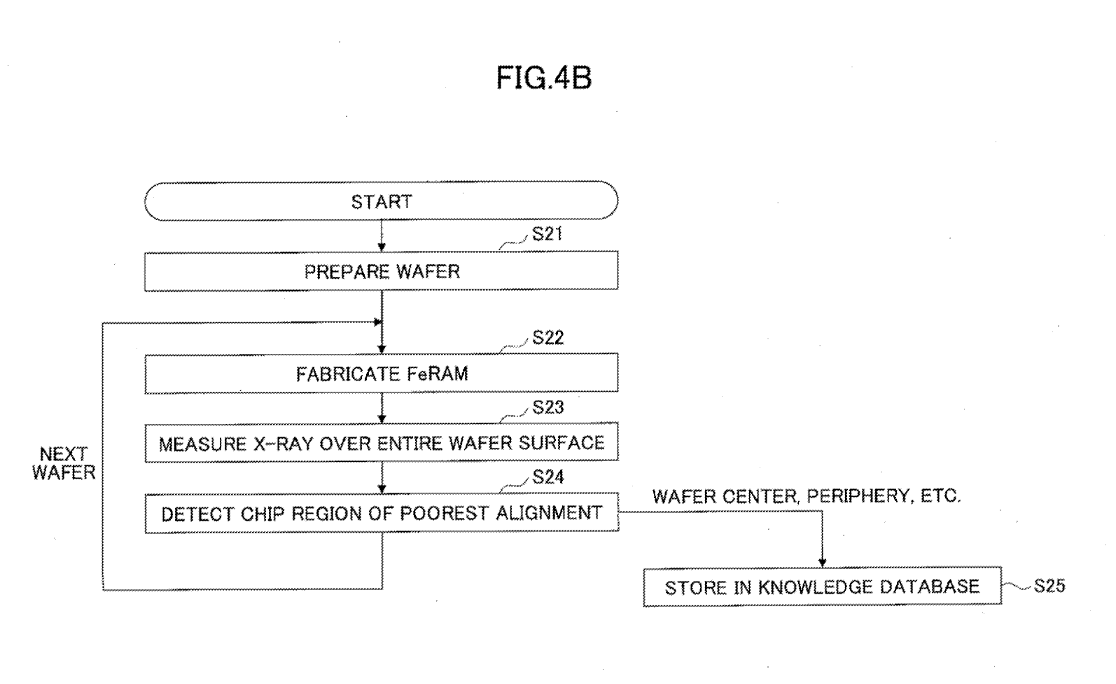

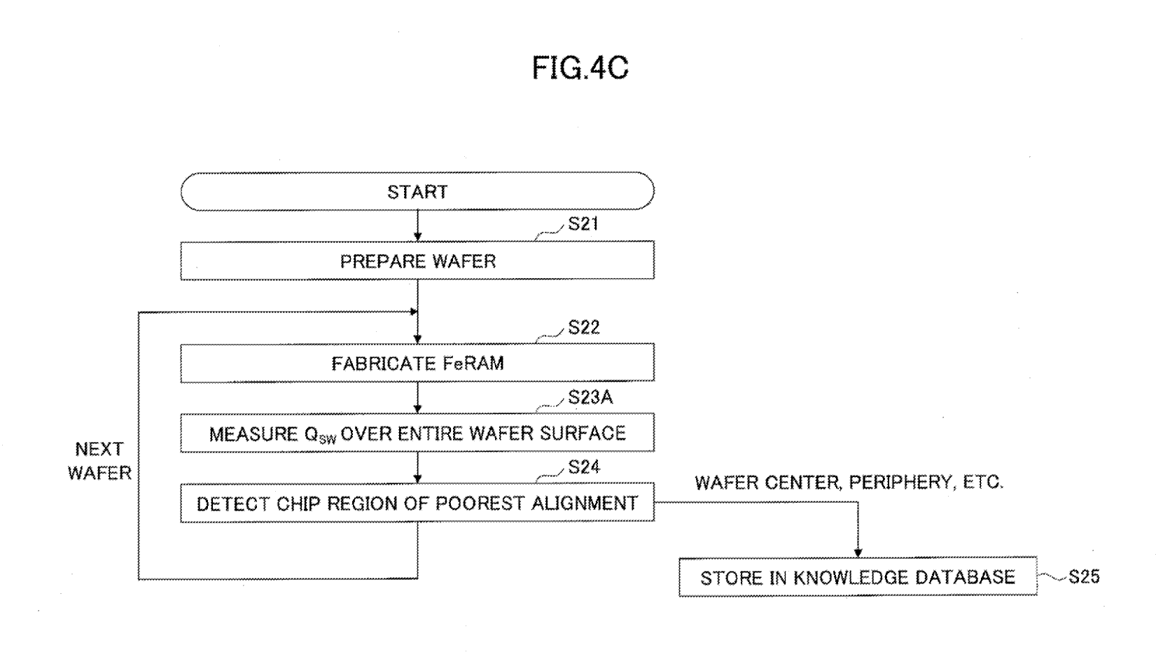

FIG. 4A is a flowchart representing the outline of the test, more particularly the fatigue test and the operational test, of the present embodiment, which is to be conducted by using the testing apparatus 40 of FIG. 3 for a wafer 60 on which the product semiconductor devices to be shipped are formed.

Referring to FIG. 4A, each chip region of the wafer 60 is formed with semiconductor devices such as the one explained with reference to FIG. 2A or 2B together with the respective ferroelectric capacitors, wherein a step 1 is conducted for fatigue test for about 10⁷ times, for example, by using monitoring patterns 60M that are formed similarly to the monitoring patterns 10M in the case of the wafer 10. With this, general quality of the ferroelectric film is confirmed based on the fatigue characteristics of the ferroelectric capacitors. The wafers failing the monitoring check of the step 1 are discarded and a next wafer is tested.

Next, in a step 2, a chip region 61C, which is expected to show the poorest fatigue properties, is designated as the specific region in the wafer 60 based on the information as to the in-plane distribution of the database of FIG. 3. In the example of FIG. 3, it is noted that the specific region 61C is located at the central part of the wafer 60. However, it should be noted that the present embodiment should not be limited to such a specific case and may include the case in which the specific region 61C is located in the peripheral part of the wafer 60. Here, it should noted that the information read out from the database 41 in the step 2 is chosen such that the manufacturing method of the ferroelectric capacitor in the information and the manufacturing method used for fabricating the ferroelectric capacitor on the wafer 60 are the same, such as forming the PZT film of the (111) orientation for the ferroelectric film of the ferroelectric capacitor by a sputtering process in both of the cases.

Next, in the step 3, the fatigue test of the ferroelectric capacitor is conducted for the specific region thus designated while using the probe 43 of FIG. 3. Such a fatigue test may be conducted at the temperature of 90° C., for example. Therein, polarization reversal is inducted repeatedly in the ferroelectric film in the test by repeatedly writing and reading data ‘0’ and data ‘1’ for a predetermined, guaranteed rewriting number of times.

In a general probe test of semiconductor devices, it is usual to use a probe card having a large number of probes for enabling test of eight chips at the same time. On the other hand, such an ordinary probe card is also capable of applying voltage and current to a specific ferroelectric memory cell of a chip under testing. Thus, such an ordinary probe card can be used also in the test of only one chip as in the present embodiment without a need for modification.

When it is judged that the fatigue characteristics of the ferroelectric capacitor are defective in the foregoing specific region 61C as a result of the fatigue test of the step 3, the wafer 60 is discarded in a step 4.

On the other hand, in the case it is judged that the wafer 60 has passed the fatigue test of the step 2, it is rendered that the entire ferroelectric memory cells on that wafer 60 are good with regard to the fatigue test, and an operational test (probe test) is conducted to that wafer 60 subsequently in a step 5. Therein, the test is conducted for the entire chips on the wafer 60 by using the probe card 43 consecutively. The test may be conducted for eight chips in one time, for example.

FIG. 4A notes the content of the operational test of the step 5.

Referring to FIG. 4A, the operational test includes a first probe test S51 that carries out writing of first data such as “101010 . . . ” to the ferroelectric capacitor at 90° C.; a first aging test S52 conducted subsequent to the first probe test S51 at 250° C., a second probe test S53 conducted subsequent to the first aging test S52 by reading the first data and further writing second data “010101 . . . ”, which is a logic inversion of the first data also at 90° C., a second aging test S54 conducted subsequent to the second probe test S52 at 250° C., and a third probe test conducted subsequent to the second aging test S54 to read out the second data also at 90° C.

As noted previously this operational test of the step 5 is conducted for the entire chip regions of the entire wafers.

Further, in a step 6, yield is determined based on the results of the operational test of the step 5, and in a step 7, the chip regions that includes the semiconductor device used for the fatigue test and further the semiconductor devices rendered defective as a result of the operational test are registered in the system, which controls the testing process of FIG. 4A, as defective chip area.

Further, in a step 8, a dicing process is conducted to divide the wafer 60 into the semiconductor chips, and good chips are selected in a step 9 by excluding the defective semiconductor chips registered in the step 9 and the semiconductor chips used in the step 2 for the fatigue test. Further, in a step 10, the selected good chips are shipped as product.

According to the present embodiment, it should be noted that the fatigue test is conducted for the entire wafers of the current lot and that the fatigue test is conducted directly in that the fatigue test is made to the semiconductor device that is the actual product. Thus, it is possible to obtain a highly reliable test result as compared with the indirect fatigue test that relies upon the sampled wafers. Further, it should be noted that the fatigue test is conducted for the chip region where the fatigue characteristics are expected to be the poorest, and thus, the time needed for the test falls in an acceptable range even when the test is conducted up to the predetermined guaranteed number of times for rewriting.

Here, it should be noted that the probe test of the step 5 is conducted after the fatigue test of the step 2. This is to avoid degradation of the imprint characteristics of the ferroelectric capacitors constituting the ferroelectric memory cells by the heat applied at the time of the fatigue test conducted for 1×10¹¹ times at the temperature of 90° C. It should be noted that, when the fatigue test is conducted before the probe test, the entire ferroelectric memory cells would be written already with the data by the probe test by the time when the fatigue test is to be conducted.

FIG. 4B is represents an example of the process of the present embodiment for acquiring the information used in the flowchart of FIG. 4A.

Referring to FIG. 4B, a silicon wafer of a predetermined diameter is prepared in a step 21 as in the case of the wafer 10 of FIG. 1, and semiconductor devices having ferroelectric capacitors such as ferroelectric memory devices are formed in respective chip regions in a step 22. For example, the silicon wafer of the predetermined diameter may be chosen to have a diameter identical to that of a silicon wafer on which the product semiconductor devices are fabricated in the step of FIG. 4A. Such a diameter may be 20 cm or 30 cm, for example.

Next, in a step 23, the upper electrode of the ferroelectric capacitor is removed to expose the ferroelectric film, and the in-plane distribution of the (111) orientation is acquired by measuring the proportion of the crystal grains of the (111) orientation in each chip region. While this X ray measurement may be conducted over the entire chip region of the wafer used for the acquisition of the information, it is also possible to reduce the time of measurement by carrying out the measurement along a specific measuring path from a center to the periphery or from the periphery to the center in the case it is known that the characteristics of the chip regions are symmetric about the central line of the wafer.

Further, in a step 24, the location in the wafer is detected for the chip region of the most inferior orientation based on the in-plane distribution thus acquired. For example, there is detected a chip region in the step 24 in which the proportion of the PZT crystal grains of the (111) orientation (designated hereinafter as “(111) orientation ratio”) is 90% or less. Further, in the case no chip region that provides the (111) orientation ratio of 90% or less is found in the step 24, the chip region having a higher (111) orientation ratio such as 93% or less, 95% or less, 98% or less, may be detected as the chip region of the most inferior orientation ratio, provided that a higher (111) orientation ratio is obtained in all the chip regions.

Further, in a step 25, the information as to the location of the chip region of the poorest orientation on the wafer obtained in the step 24 is stored in the database 41 of FIG. 3 together with the date and time of the formation of the semiconductor device in the form such as “wafer center”, “wafer peripheral”, or the like.

In the event the step 24 has detected a plurality of chip regions as having the poorest orientation ratio, these plurality of chip regions are stored in the database 41 and one of the plurality of chip regions is chose arbitrarily when designating the specific region in the step 2 of FIG. 4.

FIG. 4C is a modification of the flowchart of FIG. 4B and represents a process of obtaining the Q_{sw} characteristics for the respective chip regions on the wafer in a step 23A as an alternative of the step 23 of FIG. 4B. Otherwise, the flowchart of FIG. 4C is identical with that of FIG. 4B.

While this electric measurement may be conducted over the entire chip region of the wafer used for the acquisition of the information, it is also possible to reduce the time of measurement by carrying out the measurement along a specific measuring path from a center to the periphery or from the periphery to the center in the case it is known that the characteristics of the chip regions are symmetric about the central line of the wafer.

### Second Embodiment

As noted previously, the semiconductor device of FIG. 2A or FIG. 2B may be integrated to form a part of a larger semiconductor integrated circuit device. Hereinafter, the case the planer ferroelectric memory device of FIG. 2A constitutes a larger semiconductor integrated circuit device 80.

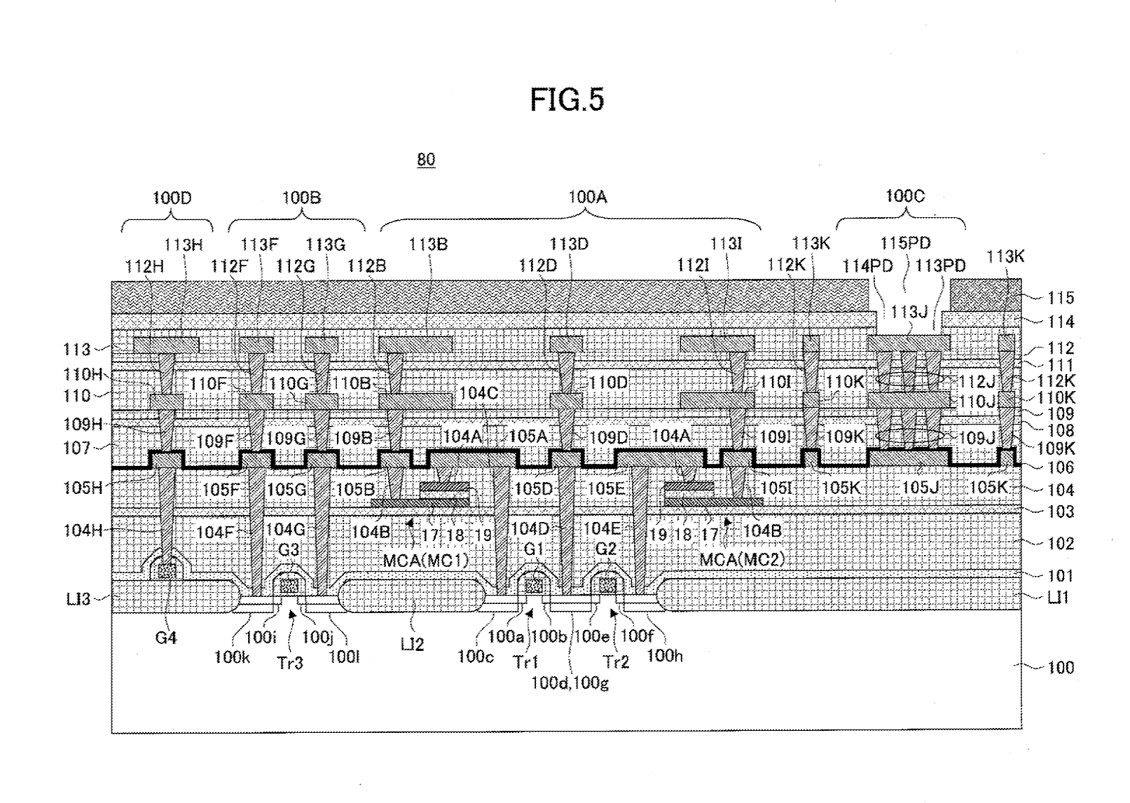

FIG. 5 is a cross-sectional diagram representing the construction of such a semiconductor integrated circuit device 80.

Referring to FIG. 5, the semiconductor integrated circuit device 80 includes a ferroelectric memory cell of the planar type and is constructed on a silicon substrate 100 corresponding to the silicon wafer 10 of FIG. 1 or the silicon wafer 60 of FIG. 4A.

Thus, on the silicon substrate 100, there are defined a device region 100A of a ferroelectric memory cell part and a device region 100B of a logic circuit part by device isolation regions LI1, LI2 and LI3 of LOCOS type, wherein it can be seen that a via-pad part 100C is formed over the device isolation region LI1 and other peripheral circuit part 100D is formed over the device isolation region LI3.

The device isolation region 100A is formed with a transistor Tr1 having a gate electrode G1 of polysilicon or amorphous silicon, a drain extension region 100a and a source extension region 100b, and a drain region 100c and a source region 100d and further a transistor Tr2 having a gate electrode G2 of polysilicon or amorphous silicon, a source extension region 100e and a drain extension region 100f, and a drain region 100g and a drain region 100h, wherein the source extension region 100b of the transistor Tr1 is shared with the source extension region 100e of the transistor Tr2 and the source region 100d of the transistor Tr1 is shared with the source region 100g of the transistor Tr2.

Further, on the device region 10B, there is formed a transistor Tr1 having a gate electrode G3, a source extension region 100i, a drain extension region 100j, a source region 100k and a drain region 100I, and a silicon pattern G4 similar to the gate electrodes G1-G3 are formed over the device isolation region LI3.

Each of the gate electrodes G1-G3 and the silicon pattern G4 is covered, together with the sidewall insulation films thereof, with an oxygen barrier film 101 of SiN or SiON formed on the silicon substrate 100, and a first interlayer insulation film 102 of a plasma TEOS film, for example, is formed on the oxygen barrier film 101 by way of a plasma CVD method that uses TEOS as a source.

Further, the top surface of the first interlayer insulation film 102 is planarized by a chemical mechanical polishing (CMP) process, and a hydrogen barrier film 103 of Al₂O₃ is formed on the planarized top source with a film thickness of 20 nm, for example.

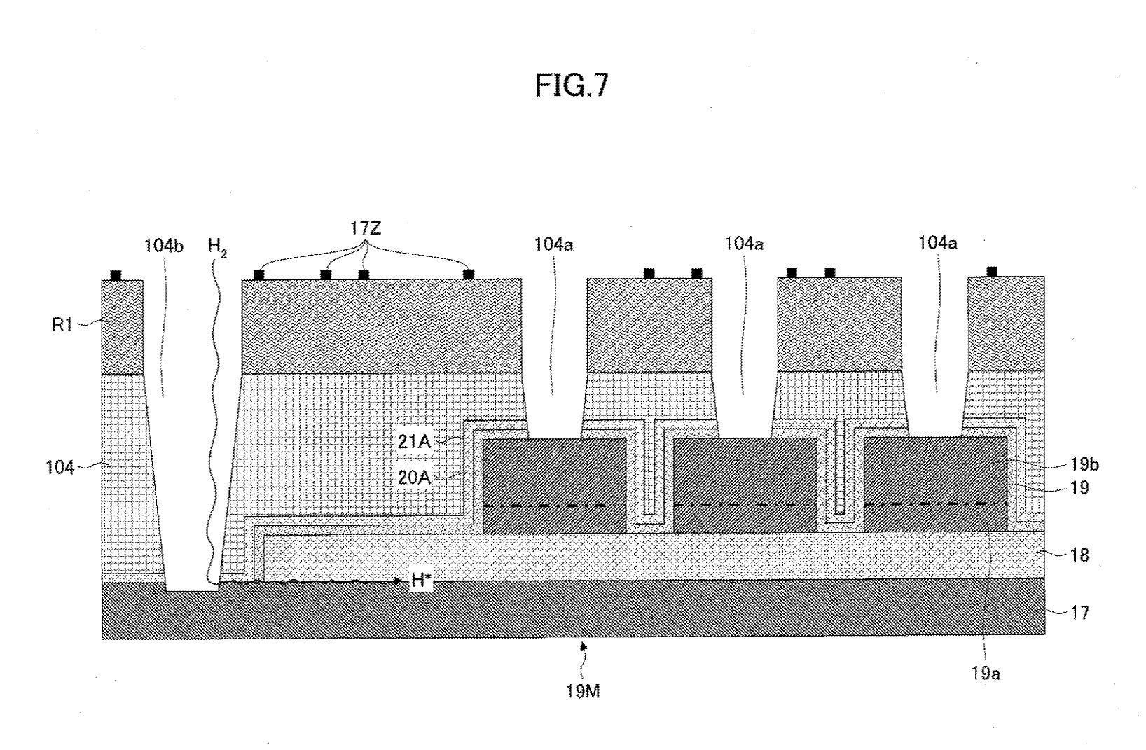

On the hydrogen barrier film 103, a Pt film corresponding to the lower electrode 17A, a ferroelectric film 18 of (111) orientation corresponding to the ferroelectric film 18A and an IrO₂ film 19 corresponding to the upper electrode 19A, of the ferroelectric capacitor MCA explained with reference to FIG. 2A, are stacked consecutively by a sputtering process, wherein the IrO₂ film 19 and the ferroelectric film 18 underneath are patterned in correspondence to the individual capacitors to expose the Pt film 17 constituting the lower electrode. Further, subsequent to the patterning of the IrO₂ film and the ferroelectric film 18, a thermal annealing process is conducted in an oxidizing ambient for recovering oxygen defects formed in the ferroelectric film, and the hydrogen barrier film 20A explained with reference to FIG. 2A (not shown in FIG. 5, reference should be made to enlarged cross-sectional vie of FIG. 7) is formed to cover the IrO₂ film 19 and the ferroelectric film 18 thus patterned.

Further, after removing the hydrogen barrier film 20A formed on the Pt film 17 by way of patterning, the Pt film is patterned to form a structure in which a plurality of ferroelectric capacitors MCA, including the ferroelectric capacitor MC1 or MC2, are aligned on the lower electrode in a predetermined direction by sharing the lower electrode of the Pt film 17.

Further, the array of the ferroelectric capacitors MCA thus formed is covered with a hydrogen barrier film (not shown in FIG. 5) corresponding to the hydrogen barrier film 21A represented in FIG. 2A, and a next interlayer insulation film 104 is formed thereon also by a plasma CVD method that uses TEOS as a source material.

Further, in the interlayer insulation film 104, there are formed a large number of via-holes to expose the upper electrodes 19 of the individual ferroelectric capacitors MCA and further a single via-hole to expose the commonly shared lower electrode 17. Further, via-plugs 104 are formed in the foregoing large number of via-holes and a via plug 104B is formed in the foregoing single via-hole.

Simultaneously, there are formed via-holes to penetrate through the interlayer insulation film 104, the hydrogen barrier film 103 underneath, the interlayer insulation film 102, and further the oxygen barrier film 101, and there are formed a via-plug 104C contacting with the source region 100c of the transistor Tr1, a via-plug 104D contacting with the drain region 100d of the transistor Tr1 and hence the source region 100g of the transistor Tr3, a via-plug 104E contacting with the drain region 100h of the transistor Tr2, a via-plug 104F contacting with the source region 100i of the transistor Tr3, a via-plug 104G contacting with the drain region 100I of the transistor Tr3, and the via-plug 104H contacting with the silicon pattern G4.

The interlayer insulation film 104 has a surface planarized by a chemical mechanical polishing process, and interconnection patterns 105A and 105B-1051 are formed on the planarized surface respectively in correspondence to the via-plugs 104A-104H. Further, on the planarized surface of the interlayer insulation film 104, there are formed an interconnection pattern 105J corresponding to the electrode pad formed in a pad region 100C and an interconnection pattern 105K surrounding the pad region and constituting a part of the guard ring. In the illustrated example, the interconnection patterns 104F-104H correspond to the via-plugs 105F-105H respectively, while the interconnection pattern 105A connects the via-plug 104A of the memory cell capacitor MC1 with the via-plug 104C, the interconnection pattern 105E connects the via plug 104A of the memory cell capacitor MC2 with the via-plug 104E and the interconnection pattern 1051 is formed in correspondence to the via-plug 104B of the memory cell capacitor 104B. With this, the upper electrode 19 of the memory cell capacitor MC1 is connected to the drain region 100c of the memory cell transistor Tr1 via the via-plug 104A, the interconnection pattern 105A and the via-plug 104C, while the upper electrode 19 of the memory cell capacitor MC2 is connected to the drain region 100h of the memory cell transistor Tr2 via the via-plug 104A, interconnection pattern 105E, and the via-plug 104E.

Over the interlayer insulation film 104, there is formed a hydrogen barrier film 106 of Al₂O₃ to cover the interconnection patterns 105A and 105B-1051 with a film thickness of 20 nm-30 nm, and an interlayer insulation film 107 is formed over the hydrogen barrier film 106 for example by a plasma CVD method that uses TEOS as a source material. The interlayer insulation film 107 is planarized.

Further, on the planarized top surface of the interlayer insulation film 107, there is formed an oxygen barrier film 108 of Al₂O₃ with a thickness of 50 nm, for example, and a next interlayer insulation film 109 is formed thereon by a plasma CVD method that uses TEOS as a source material. The interlayer insulation film 109 and the underlying hydrogen barrier film 108 have respective flat surfaces corresponding to the planarized surface of the interlayer insulation film 107.

Next, there are formed via-plugs 109B and 109D-109K in the interlayer insulation film 109 in the illustrated example through the interlayer insulation film 107 and the hydrogen barrier film 106, and via-plugs 109B and 109D-109K are formed respectively in correspondence to the interconnection patterns 105B and 105D-105K. The via-plug 109J corresponding to the via-pad part 100C is actually formed by an array of a large number of via-plugs for supporting the via-pad to be formed. In FIG. 5, the array of these via-plugs is designated collectively as a via-plug 109J.

On the interlayer insulation film 109, there are formed interconnection patterns 110B and 110D-110K respectively in correspondence to the via-plugs 109B and 109D-109K, wherein a next interlayer insulation film 110 is formed over the interlayer insulation film 109 to cover the interconnection patterns 105B and 105D-105K by a plasma CVD method that uses TEOS as source material. Further, on the interlayer insulation film 110, there is formed an oxygen barrier film 111 of Al₂O₃ with a thickness of 50 nm, for example, and a next interlayer insulation film 1112 is formed on the oxygen barrier film 111 also by a plasma CVD method that uses TEOS as a source material. The interlayer insulation film 112 and the underlying hydrogen barrier film 111 and further the interlayer insulation film 110 have respective flat surfaces corresponding to the planarized surface of the interlayer insulation film 109.

In the interlayer insulation film 112, there are formed via-plugs 112B and 112D-112K respectively corresponding to the interconnection patterns 110B and 110D-110K, and wherein interconnection patterns 113B and 113D-113K are formed on the interlayer insulation film 112 respectively in correspondence to the via-plugs 112B and 112D-112K. Here, the interconnection pattern 113J constitute a via-pad in the via-pad part and is surrounded with an interconnection pattern 113K constituting the guard ring.

Further, a next interlayer insulation film 113 is formed on the interlayer insulation film by a plasma CVD process that uses TEOS as a source for example so as to cover the interconnection patterns 113B and 113D-113K, wherein the interlayer insulation film 113 is formed with an opening 113PD exposing the via-pad 113J.

Further, a passivation film 114 of SiN, or the like, is formed on the interlayer insulation film 113 wherein the passivation film 114 is formed with an opening 114PD in coincidence with the opening 113PD. Actually, it is preferable that the opening 113PD is formed simultaneously to the opening 114PD.

The passivation film 114 is covered with a polyimide protective film 115, and the polyimide protective film is formed with an opening 115PD exposing the via-pad 113J via the opening 114PD.

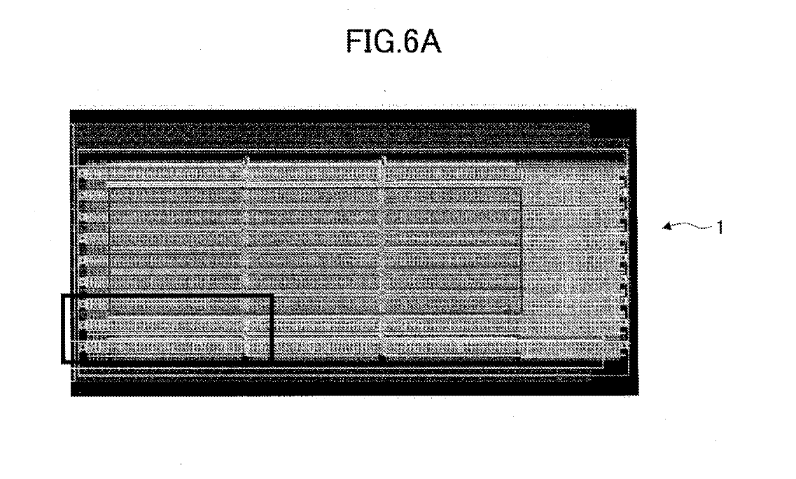

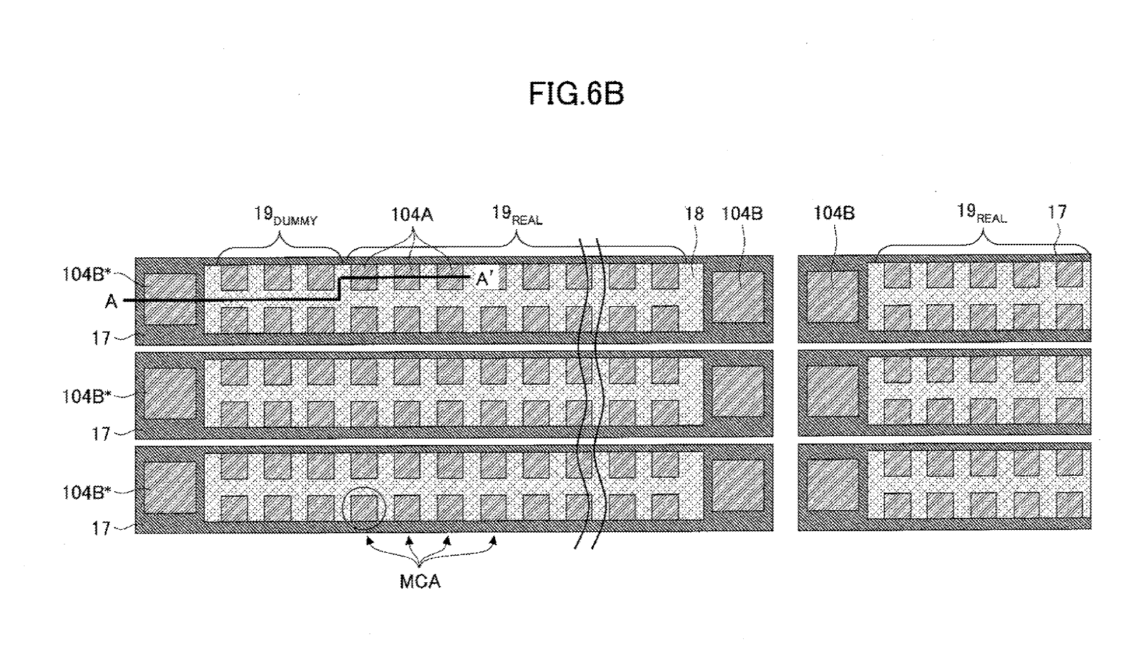

FIG. 6A is a plan view diagram representing the entirety of the memory cell array 1 formed in the semiconductor integrated circuit device in which such a ferroelectric memory are integrated, while FIG. 6B is an enlarged plan view diagram representing a part of the memory cell array 1 surrounded by a frame in FIG. 6A with enlarged scale.

Referring to FIG. 6B in particular, it can be seen that each of the lower electrodes 17 of Pt has a stripe shape and are arranged in the memory cell array in a row and column formation will maintaining a parallel relationship with each other.

On each of the lower electrodes 17, the ferroelectric film 18 is formed in the form of a stripe corresponding to the lower electrode 17 in terms of size and shape, and a large number of via-plugs 104A are formed on the ferroelectric film 18 in two rows in correspondence to the individual memory cell capacitors MCA. In the illustration of FIG. 6B, the stripe pattern formed by the lower electrode 17 is drawn to have a width larger than the width of the stripe pattern formed by the ferroelectric film 18 for the purpose of drawing the lower electrode 17 visible. However, they are actually patterned with the same pattern width.

Drawing attention to one specific lower electrode 17, it can be seen that there are formed via-plugs 104B at both ends of the stripe-shaped lower electrode 17, wherein these via-plugs 104B are formed in common to the large number of ferroelectric capacitors MCA that are formed on the lower electrode 17 respectively in correspondence to the large number of upper electrodes 19.

In the example, a via-plug 104B* at the left end corresponds to the via-plug 104 formed at the left end of the memory cell array 1 of FIG. 6A. Because the ferroelectric capacitors thus formed in the peripheral part of a large memory cell array 1 exhibits a tendency of having defective characteristics due to various reasons, 2-3 ferroelectric capacitors as counted from the edge of the memory cell array are not used for writing or reading of data and are rendered as dummy memory cells or unused memory cells. Thus, the dummy memory cells constituting the dummy cell array 19_{DUMMY} are not used for the operation of the semiconductor device. What is actually used in the ferroelectric memory for writing and reading of data are the active or operable memory cells designated as real memory cell array 19_{REAL} located at an inner side of the dummy cell array 19_{DUMMY}. Thus, in the active memory cells in the real memory cell array 19_{REAL}, ordinary wiring and reading operation is conducted. Here, any of the active memory cells constituting the real cell array 19_{REAL} and the dummy memory cells constituting the dummy cell array 19_{DUMMY} has the construction that includes a ferroelectric capacitor MCA and a transistor such as the transistor Tr1 or Tr2 that drives the ferroelectric capacitor MCA.

FIG. 7 is a cross-sectional diagram of the memory cell array of FIG. 6B taken along a line A-A′ for the state before the formation of the via-plugs 104A and 104B. In the cross-sectional diagram of FIG. 7, the dummy cells are not illustrated.

Referring to FIG. 7, there is formed a resist pattern R1 on the interlayer insulation film 104 wherein the interlayer insulation film 104 is formed with a via-hole 104b for the via-plug 104B so as to expose the lower electrode 17 by a dry etching process that uses the resist pattern R1 as a mask. Further, in the interlayer insulation film 104, there is formed a via-hole 104a for the via-plug 104A in the interlayer insulation film 104 in correspondence to the ferroelectric capacitor MCA that constitutes the ferroelectric memory cell such that the via-hole 104a exposes the upper electrode 19. In the illustrated example, the upper electrode 19 of IrO₉ may be formed of a stacked structure of lower part electrode 19a having a non-stoichiometric composition IrOx and having a lower degree of oxidation and an upper part electrode 19b having a stoichiometric composition IrO₂ or a near composition and hence having a higher degree of oxidation.

With such a structure, a part of the lower electrode 17 of Pt may be scattered at the time of formation of the via-hole 104b and the scattered Pt may be deposited on the top part of the resist pattern R1 in the form of an impurity particle 17Z having the composition of predominantly Pt.

Because the resist pattern R1 is generally formed of a compound of carbon and hydrogen, there can be a case in which hydrogen is released by the action of plasma during the dry etching process and the released hydrogen is activated to form active hydrogen H* by the catalytic action of the impurity particle 17Z predominantly of Pt. When such active hydrogen H* penetrates into the memory cell array 1 along the interface between the lower electrode 17 and the ferroelectric film 18, there is induced reduction in the ferroelectric such as PZT that constitutes the ferroelectric film 18, and the ferroelectric memory cell can no longer maintain the ferroelectricity. Further, the hydrogen thus penetrated into the via-hole 104 is also activated by the catalytic action of the Pt that constitutes the lower electrode 17, wherein the hydrogen thus activated also functions to reduce the ferroelectric film 18.

From FIG. 7, it can be seen that the memory cell 19M is the nearest memory cell of the real cell array 19_{REAL} to the via-hole 104, and thus, it is expected that the reduction of the ferroelectric film 18 by hydrogen appears most conspicuously in the memory cell 19M. While there is a possibility that the hydrogen penetrates also into the via-hole 104a, no serious problem is expected to be caused in the characteristics of the ferroelectric film 18 as the upper electrode part 19b of the upper electrode 19 has a near stoichiometric composition IrO₂ and that the upper electrode 19 does not contain Pt.

Thus, from these considerations above, it is expected that, in the semiconductor integrated circuit device 80 of the present embodiment that has a memory cell array of ferroelectric memory cells, it is the active memory cell 19M located closest to the lower electrode via-hole 104b and thus closest to the hydrogen source, that exhibits the severest deterioration of the ferroelectric film among the active memory cells of the real cell array 19_{REAL} of the semiconductor chip, which in turn is located at the central part of the silicon wafer 60 corresponding to the silicon substrate 100.

Thus, with the present embodiment, the predetermined number of times for rewriting is guaranteed for the semiconductor chips formed on a wafer, by designating a specific region at the wafer central part where the degradation of the ferroelectric film is the severest based on the in-plane distribution of the crystal orientation or fatigue characteristics on the wafer, and further by designating a specific ferroelectric memory cell located closest to the lower electrode via-hole 104b among the memory cells of the memory cell array in the selected specific region, and further by conducting the fatigue test thereto for the predetermined number of times. When such a specific ferroelectric memory cell has passed the predetermined fatigue test, it would be reasonable to consider that the remaining ferroelectric memory cells, expected to have superior characteristics, should also pass the fatigue test.

After the step of FIG. 7, the via-holes 104a and 104b are filled with tungsten and the via-plugs 104A and 104B are formed.

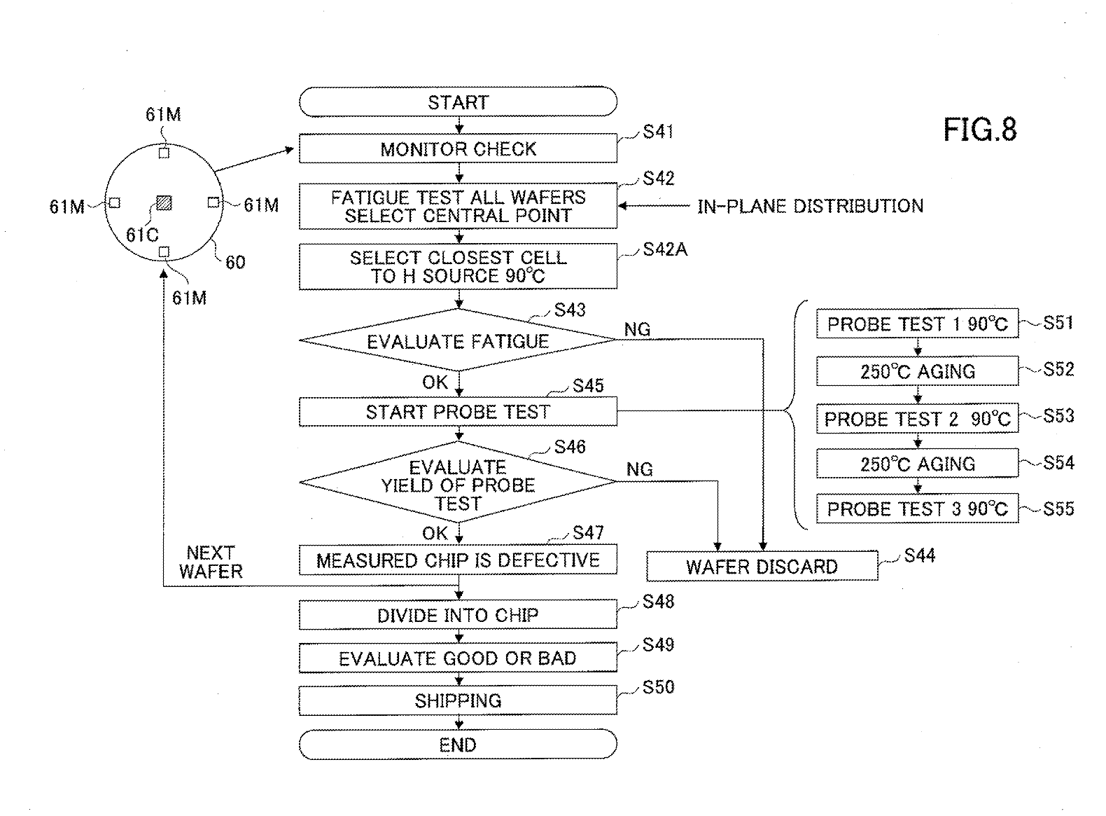

FIG. 8 is a flowchart according to the present embodiment representing the outline of the test, that is the fatigue test and the operational test, conducted to the wafer on which the ferroelectric memory devices of FIG. 5 are formed.

Referring to FIG. 8, the semiconductor integrated circuit device of FIG. 7 is formed on the silicon wafer 60 in the present embodiment with respective ferroelectric capacitors, wherein the fatigue test is conducted in the step 41 for about 10⁷ times by using the monitoring patterns 60M for confirmation of the general quality of the ferroelectric film based on the fatigue characteristics of the ferroelectric capacitors. The wafers failed the monitoring check of the step 41 are discarded and a next wafer is tested. It should be noted that the formation of the ferroelectric capacitors on the wafer 60 is conducted according to the manufacturing method, such as sputtering of a (111) oriented PZT film, which is the same method used for forming the ferroelectric film at the time when acquiring the information to be stored in the database 41 of FIG. 3.

Next, in the step 42, the chip region on the wafer 60 where the degree of the (111) orientation is the poorest is designated based upon the in-plane information acquired by the process explained with reference to FIG. 4B or FIG. 4C. In the case a PZT film formed by a sputtering process or sol-gel process is used for the ferroelectric film 18, the chip region 61C at the central part of the wafer is selected in the step 42. As noted previously, the chip region selected by the step 42 may be other than the wafer central part in the case different fabrication process or different material system is used.

Next, in the step 42A, the active memory cell closest to the via-plug 104B to the lower electrode is selected among the active memory cells of the memory cell array of the selected chip region 61C, and the fatigue test is conducted to the ferroelectric capacitor constituting the selected active memory cell for a predetermined, guaranteed number of times such as 1×10¹¹ times by conducting writing and reading at 90° C. When there exist a plurality of active memory cells in the designated specific region that are both located closest to the via-plug 104B, one of the active memory cells is selected arbitrarily among the foregoing plurality of active memory cells.

Further, in the step 43, the fatigue characteristics is evaluated for the active memory cell designated in the step 42A by repeating the writing and reading for the predetermined guaranteed number of times such as 1×10¹¹ or more. When the predetermined fatigue characteristics are not attained, the wafer is discarded in the step 44 and a next test is started in the step 41 with a next wafer.

On the other hand, when the designated active memory cell of the designated chip region has passed the fatigue characteristic test as a result of the step 43, the operational test (probe test) explained previously with reference to FIG. 4A is conducted in a step 45. As noted previously, this operational test is conducted for the entire memory cells of the entire chip regions on the wafer 60. The content of the step 45 is the same as in the flowchart of FIG. 4A and thus includes the probe test 1 conducted in the step 51 at 90° C., the aging test in the step 52 conducted at 250° C., the probe test 2 in the step 53 conducted at 90° C., the aging test in the step 54, and the probe test 3 in the step 55 at 90° C.

Further, in a step 46, yield is determined based on the results of the operational test of the step 45, and in a step 47, the semiconductor chips that includes the semiconductor device used in the fatigue test or the semiconductor devices rendered defective as a result of the operational test are registered in the system, which controls the testing process of FIG. 4A, as defective chip area.

Further, in a step 48, a dicing process is conducted to divide the wafer 60 into the semiconductor chips, and good chips are selected in a step 49 by excluding the defective semiconductor chips registered in the step 49 and also the semiconductor chip used in the step 42 for the fatigue test. Further, in a step 50, the selected good chips are shipped as product.

### Third Embodiment

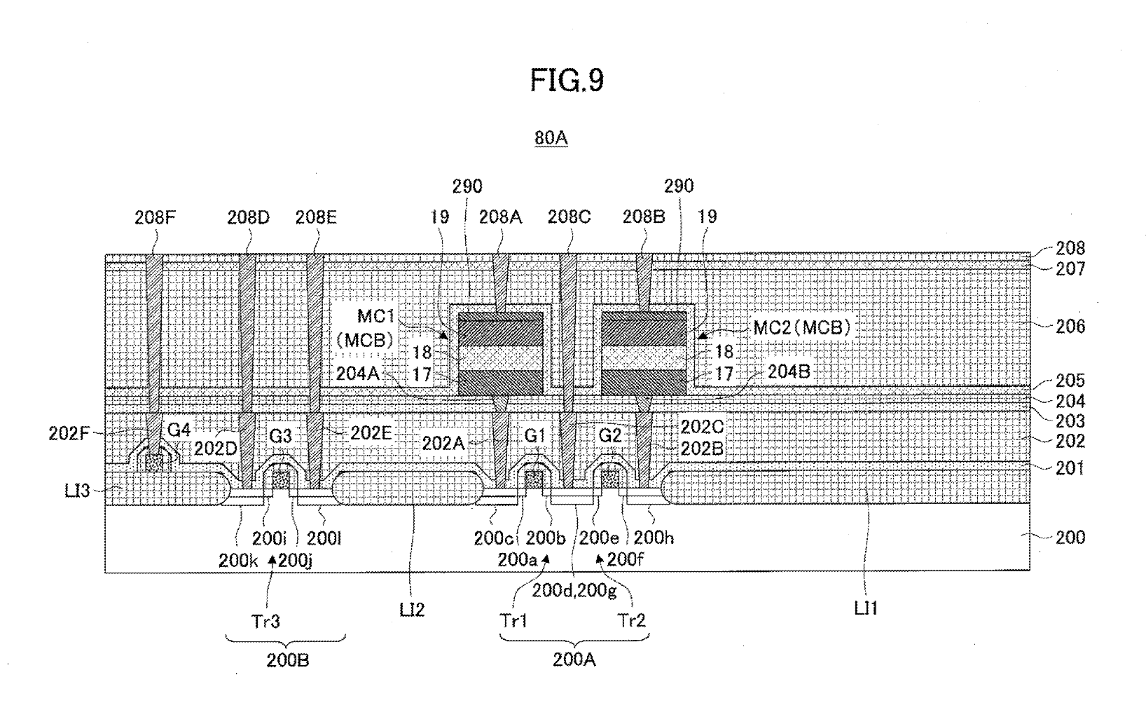

FIG. 9 is a cross-sectional diagram representing the construction of a semiconductor integrated circuit device 80A in which the ferroelectric memory device of the stacked type explained with reference to FIG. 2B are integrated.

Referring to FIG. 9, the semiconductor integral circuit device 80A is formed on a silicon wafer 200 corresponding to the silicon wafer 10 of FIG. 1 or the silicon wafer 60 of FIG. 4, wherein the silicon wafer 200 is defined with a device region 200A for the ferroelectric cell part and a device region 100B for the logic circuit part by a device isolation regions LI1, LI2 and LI3 of LOCOS type.

The device isolation region 200A is formed with a transistor Tr1 having a gate electrode G1 of polysilicon or amorphous silicon, a drain extension region 200a and a source extension region 200b, and a drain region 200c and a source region 200d and further a transistor Tr2 having a gate electrode G2 of polysilicon or amorphous silicon, a source extension region 200e and a drain extension region 200f, and a drain region 200g and a drain region 200h, wherein the source extension region 200b of the transistor Tr1 is shared with the source extension region 200e of the transistor Tr2 and the source region 200d of the transistor Tr1 is shared with the source region 200g of the transistor Tr2.

Further, on the device region 200B, there is formed a transistor Tr3 having a gate electrode G3, a source extension region 200i, a drain extension region 200j, a source region 200k and a drain region 2001, and a silicon pattern G4 similar to the gate electrodes G1-G3 are formed over the device isolation region LI3.

Each of the gate electrodes G1-G3 and the silicon pattern G4 is covered, together with the sidewall insulation films thereof, with an oxygen barrier film 200 of SiN or SiON formed on the silicon substrate 201, and a first interlayer insulation film 202 is formed on the oxygen barrier film 201 by way of a plasma CVD method that uses TEOS as a source.

In the first interlayer insulation film 202, there are formed a via-plug 202A electrically contacting with the drain region 200c of the transistor Tr1 through the oxygen barrier film 201 underneath, a via-plug 202B electrically contacting with the drain region 200c of the transistor Tr2 via the oxygen barrier film 201, a via-plug 202C electrically contacting with the source region 200d of the transistor Tr1 and hence the source region 200g of the transistor Tr2 via the oxygen barrier film 201, a via-plug 202D electrically contacting with the source region 200k of the transistor Tr3 via the oxygen barrier film 201, a via-plug 202E electrically contacting with the drain region 2001 of the transistor Tr3 via the oxygen barrier film 201, and a via-plug 202F electrically contacting with the silicon pattern G4 via the oxygen barrier film 201.

Further, the top surface of the first interlayer insulation film 202 is planarized by a chemical mechanical polishing (CMP) process, and a hydrogen barrier film 203 of Al₂O₃ is formed on the planarized top source with a film thickness of 20 nm, for example.

On the planarized oxygen barrier film 203, there is formed a thin interlayer insulation film 203 by a plasma CVD method that uses TEOS as a source with a flat surface, and the interlayer insulation film is formed with a via-plug 204A and 204B respectively making electrical contact with the via-plug 202A and the via-plug 202B via the hydrogen barrier film 203 underneath.

Further, on the interlayer insulation film 204, there are stacked consecutively a Pt film 17 corresponding to be lower electrode 17B of the ferroelectric capacitor MCB explained with reference to FIG. 2B, a PZT film 18 of the (111) orientation corresponding to the ferroelectric film 18B and an IrO2 film 19 corresponding to the upper electrode 19B.

The stack of the Pt film 17, the PZT film 18 and the IrO₂ film 19 thus formed is subjected to a patterning process in correspondence to the respective memory cell transistors such as the transistor Tr1 and the transistor Tr2, and thus, there are formed ferroelectric capacitors MC1 and MC2 respectively on the via-plugs 204A and 204B as the memory cell capacitor MCB in the form of consecutive stacking of the Pt film 17, the (111) oriented PZT film 18 and the IrO₂ film 19 formed by sputtering process. In the illustrated example, there is formed a thin Pt film 290 on the top of the upper electrode of the IrO₂ film in each of the ferroelectric capacitors MCB.

The ferroelectric capacitors MCB thus formed are covered with a hydrogen barrier film 205 of Al2O3 deposited on the interlayer insulation film 204 with a film thickness of 50 nm, for example, and a next interlayer insulation film 2063 is formed on the hydrogen barrier film 205 also by a plasma CVD method that uses TEOS as the source so as to cover the ferroelectric capacitors MCB.

The interlayer insulation film 206 has a top surface planarized by a chemical mechanical process, and a next hydrogen barrier film 207 of Al₂O₃ and a next interlayer insulation film 208 are formed consecutively on the interlayer insulation film 206. The interlayer insulation film 208 is formed by a plasma CVD method that uses TEOS as the source.

Further, in the interlayer insulation film 208, there are formed via-plugs 108A and 108B respectively in contact with the Pt film 290 constituting a part of the upper electrodes of the ferroelectric capacitors MCB, and hence the ferroelectric capacitors MC1 and MC2, through the hydrogen barrier film 207 underneath and further through the interlayer insulation film 206 and the hydrogen barrier film 205. Further, the interlayer insulation film 208 is formed with via-plugs 208C, 208D, 208E and 208F respectively in contact with the via-plugs 202C, 202D, 202E and 202F consecutively through the hydrogen barrier film 207, the interlayer insulation film 206, the hydrogen barrier film 205, the interlayer insulation film 204 and the hydrogen barrier film 203.

Further, an interconnection pattern not illustrated may be formed on the interlayer insulation film 208.

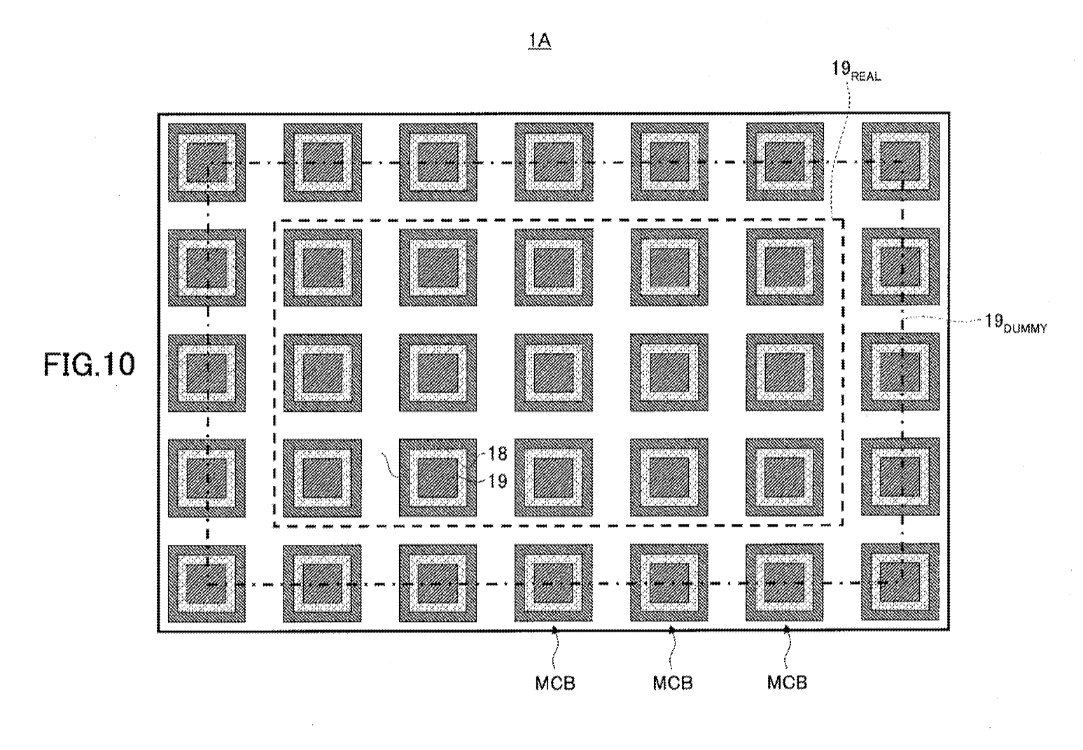

FIG. 10 is a plan view diagram representing the outline of the memory cell array 1A formed in the semiconductor integrated circuit device 80A in which the ferroelectric memory devices of the stacked type are integrated.

Referring to FIG. 10, the memory cell array 1A includes an array of active memory cells in the form of a real memory cell array 19-REAL as surrounded by a broken line, and it can be seen in the illustrated example, that there are formed dummy cells forming a dummy cell array 19_{DUMMY} so as to surround the real memory cell array 19_{REAL} in the form of a single row.

In the illustration of FIG. 10, the lower electrode 17 is drawn with the largest size and the upper electrode 19 is drawn with the smallest size, while this is merely for the purpose that the lower electrode 17 and the ferroelectric film 18 are visible in the plan view of the ferroelectric capacitor MCB constituting the memory cell array 1A, and the lower electrode 17, the ferroelectric film 18 and the upper electrode 19 may have the same shape as represented in the cross-sectional view of FIG. 9.

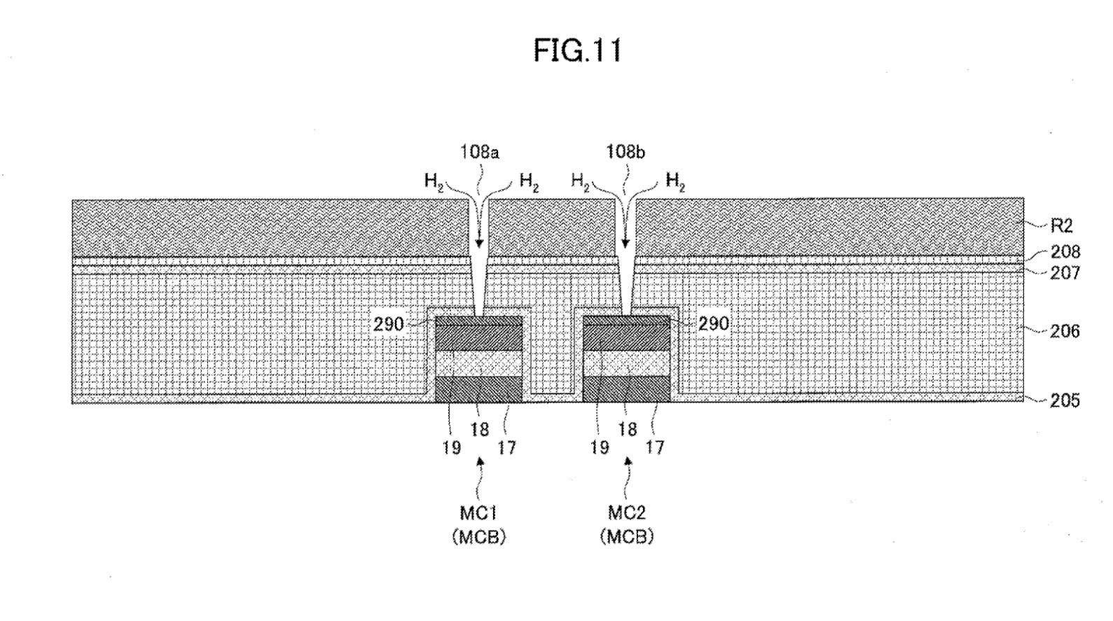

FIG. 11 represents a process of forming via-plugs such as the via-plugs 208A and 208B for electrical connection to the upper electrode after the ferroelectric capacitors MCB such as MC1 and MC2 are formed in the memory cell array 1A.

Referring to FIG. 11, such a process is conducted by forming a resist film R2 of an organic substance and hence can act as the hydrogen source upon the interlayer insulation film 208 and then by forming the via-holes 208a and 208b respectively for the via-plugs 208A and 208B in the interlayer insulation film 208 such that the via-holes 208a and 208b extend through the hydrogen barrier film 207 underneath and further the interlayer insulation film 206 while using the resist film R2 as a mask, until the Pt film 290 covering the upper electrode 19 of the ferroelectric capacitors MC1 and MC2 is exposed.

With such a patterning process, however, there arises the problem that the ferroelectric film 18 is reduced when the hydrogen released from the resist film R2 enters the via-holes 208a and 208b and activated therein by the Pt film 290.

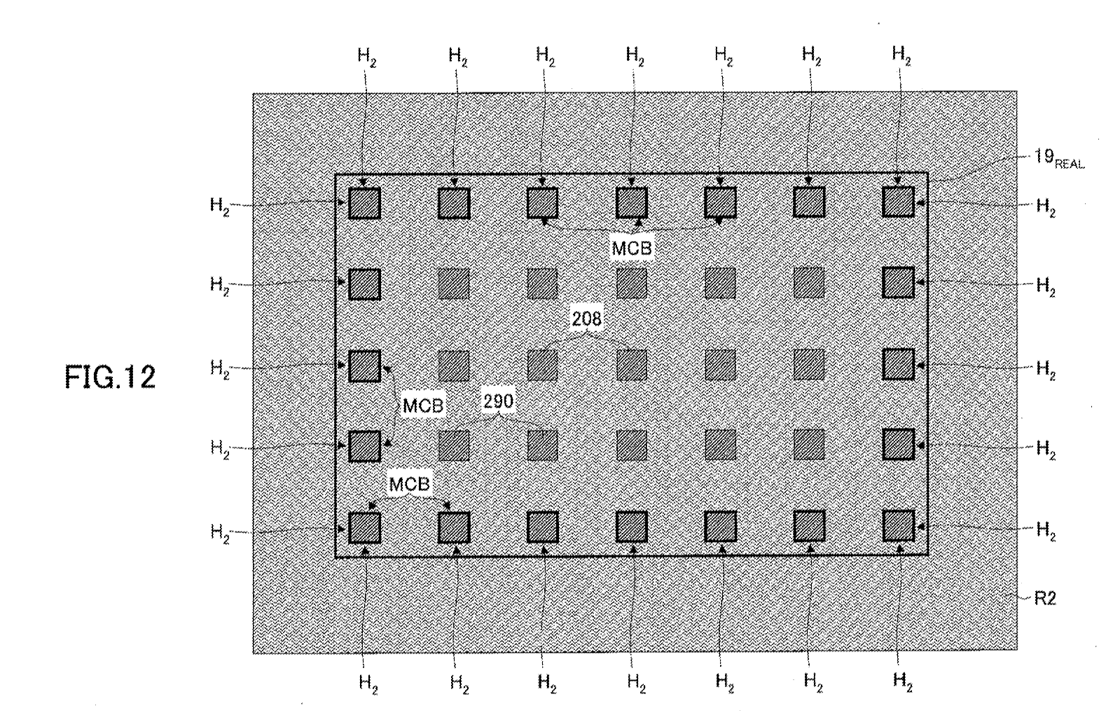

Thus, it is generally practiced in the art to apply a thermal annealing process, after the step of forming the upper via-holes as represented in FIG. 11, to the ferroelectric capacitors MCB in an oxygen ambient after removing the resist film R2 such that a recovery process for the oxygen defects is applied to the ferroelectric film. On the other hand, with the ferroelectric capacitors MCB that are disposed in the outermost part of the memory cell array 1A represented in FIG. 12 by a thick line, it can be seen that there exists a large amount of resist film R2 not patterned with the openings in the outside of the memory cell array 1A, and because of this, there is a tendency that the foregoing ferroelectric capacitors MCB represented by the thick line is influenced more heavily with the hydrogen than the ferroelectric capacitors that are located at inner side and represented by a thin line. In other words, it is expected that the fatigue characteristics are degraded most severely by the hydrogen released from the hydrogen source of the resist film R2 in the ferroelectric capacitors MCB disposed in the outermost periphery. Particularly, the ferroelectric capacitors located at the corner part are tending to experience the degradation most severely in view of the fact that the hydrogen is supplied from two directions. In FIG. 12, it should be noted that only the active memory cells forming the real cell array 19_{REAL} are illustrated in the memory cell array 1A of FIG. 10 and the illustration of the dummy cell array 19_{DUMMY} at the outer side thereof is omitted.

Thus, with the present embodiment, a memory cell located in the outermost periphery of the real memory cell array 19_{REAL}, preferably the memory cell located at the corner part thereof is selected as the memory cell that exhibits the poorest fatigue characteristics in the fatigue test of the step 42A when conducting the test of FIG. 8, and the fatigue test is conducted to the ferroelectric capacitor MCB thus selected for the predetermined times. Here, it should be noted that FIG. 12 is a plan view diagram corresponding to the cross-section of FIG. 11 and it can be seen that the ferroelectric capacitors MCB are arranged in a row and column formation to form an array, and the Pt film 290 covering the upper electrode 19 of the ferroelectric capacitor MCB is exposed in the via-hole 208 in correspondence to the via-holes 208a and 208b.

When the fatigue characteristics of the real memory cell that is expected to show the severest deterioration in the fatigue characteristics have failed the fatigue test in the subsequent evaluation step 43 for the fatigue characteristics, the wafer is discarded in the step 44 of FIG. 8. When the fatigue characteristics have passed the test, the testing process proceeds to the next step 46.

The steps of FIG. 8 after this are identical to those explained before.

Meanwhile, the selection of the memory cell for the fatigue test explained with reference to FIG. 12 is also effective I the fatigue test of the semiconductor integrated circuit device 80 in which the ferroelectric memory deices of planar type represented in FIG. 5 are integrated.

Thus, in the memory cell array 1 represented in FIGS. 6A and 6B, the memory cell MCA circled in FIG. 6B is the real memory cell located closest to the corresponding via-hole 104b and thus tends to experience severest deterioration in the fatigue characteristics. Further, this memory cell is most susceptible to the effect of hydrogen from the resist film R1 surrounding the memory cell array 1. This is because the resist film R1 represented in FIG. 7 extends continuously outside the illustrated memory cell array without being patterned and constitutes a large scale hydrogen source. Thus, the outermost periphery of the real memory cell array 19REAL is most susceptible to the effect of hydrogen in the memory cell array. In FIG. 6B, the circled memory cell MCA is located in the outermost periphery of the real memory cell array 19_{REAL}, and thus, is more susceptible to the effect of hydrogen as compared with the inner memory cells MCA. At the same time, the circled memory cell MCA is located closest to the via-plug 104B*, while this means that the circled memory cell MCA is most susceptible to the effect of hydrogen penetrated into the via-hole 104b at the time of formation of the via-plug 1048* as represented in FIG. 7.

Thus, by selecting such a memory cell for the testing in the step 42A of FIG. 8, it becomes possible to avoid that the semiconductor chips of defective fatigue characteristics are included in the semiconductor chips that are shipped as product without undue load for the testing.

### Fourth Embodiment

In the testing process explained previously with reference to FIG. 4 or FIG. 8, the fatigue test of the step 2 is conducted prior to the operational test of the step 5. Thus, there can be a case in which the ferroelectric capacitor of the specific region used in the fatigue test of the step 2 may be a defective device not operating properly.

In the present embodiment, there is conducted a step 0 immediately after the start of the testing to select the memory cell of the specific region designated by the information and used for the fatigue test, and the operational characteristics thereof are tested similarly to the step 5.

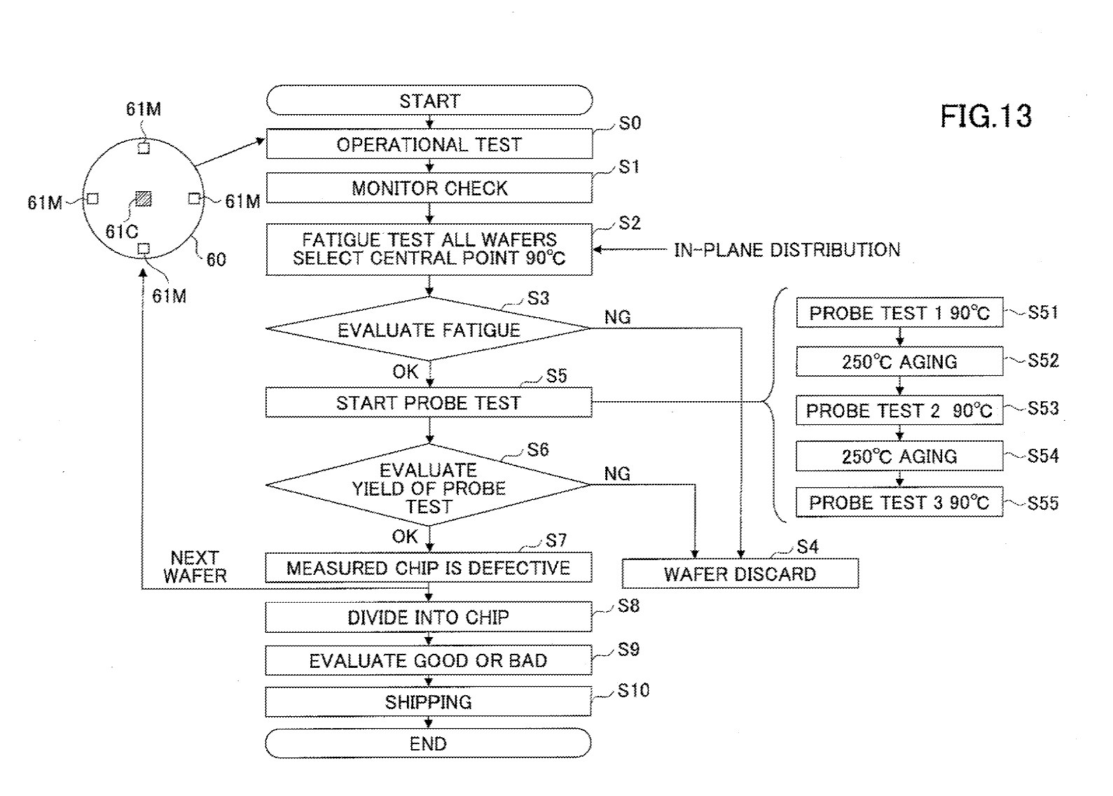

FIG. 13 is a flowchart representing an outline of the test conducted with the fourth embodiment. In FIG. 13, those parts explained in the previous embodiments are designated by the same reference numerals and the description thereof will be omitted.

Referring to FIG. 13, the testing proceeds to the step 1 when the specified memory cell has passed the operational test of the step 0, and the test explained with reference to FIG. 4 or FIG. 8 is conducted in such a case. On the other hand, when the memory cell has failed and the fatigue test is not possible, another real memory cell MCA of FIG. 6B such as the real memory cell MCA next to the circled memory cell MCA at the right side is selected as an alternative memory cell and the operational test of the step 0 is conducted again.

The operational test of the step 0 is discontinued immediately when there is found a specified memory cell that has passed the operational test and the process proceeds to the step 1 for confirmation of the wafer uniformity. Further, the fatigue test of the step 2 is conducted while using the memory cell that has passed the test. It should be noted that the candidate for such alternative memory cell is not limited to the adjacent real memory cells but it is also possible to select the memory cell that is the closest to the via-plug 104B* from the remaining three corners of the memory cell array 1 of FIG. 6A, for example. Further, with the memory cell array of the stacked type of FIG. 12, any of the real memory cells represented by a thick line can be selected.

Meanwhile, when such an operational test is conducted for all of the memory cells on the wafer, there arises concern that the entire memory cells may become defective when the fatigue test is applied thereafter. Thus, the operational test of the step 0 is limited to the specific chip region which is rendered defective after the test.

### Fifth Embodiment

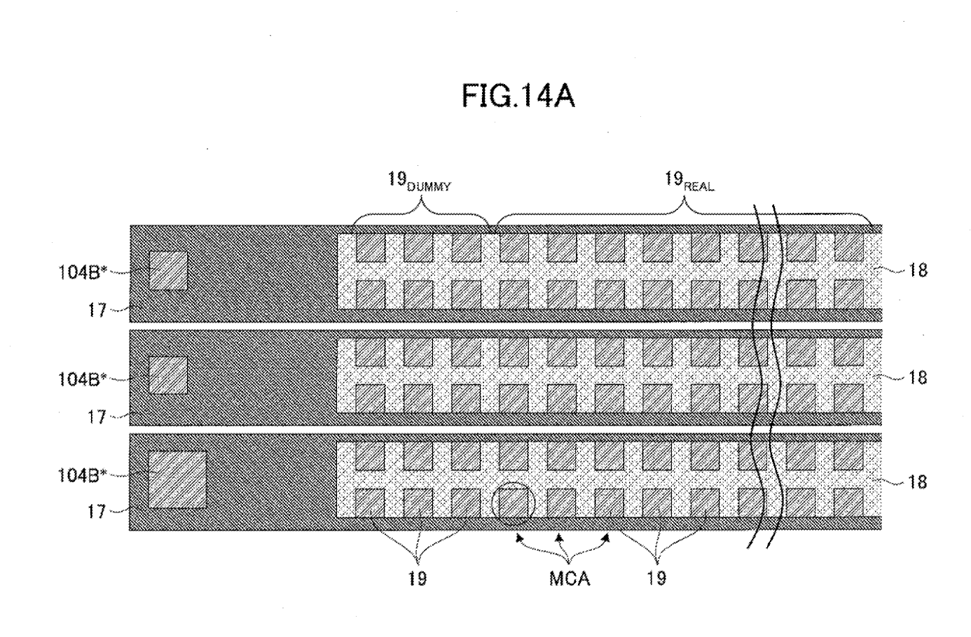

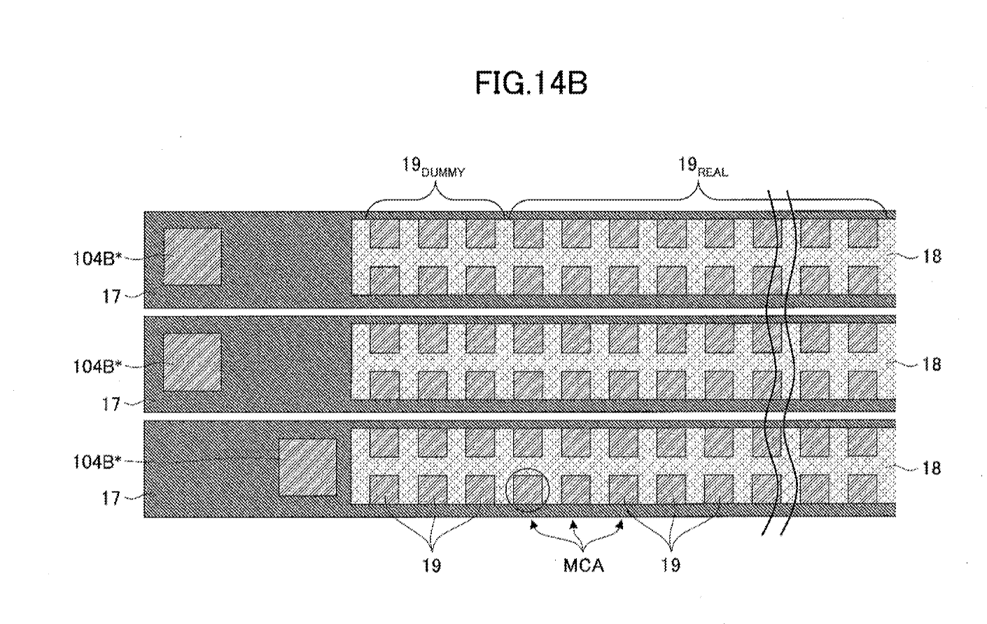

FIG. 14A is a plan view diagram representing the construction of a semiconductor device according to a fifth embodiment, particularly the construction of the ferroelectric memory cell thereof. In the drawings, those parts explained before are designated by the same reference numerals and the description thereof will be omitted.

More specifically, FIG. 14A represents the plan view diagram of a planar-type ferroelectric memory cells.

Referring to FIG. 14A, the plan view diagram of FIG. 14A corresponds to the plan view diagram of FIG. 6B explained previously, wherein the present embodiment increases the diameter of the via-plug 104B**, which is the closest to the circled real memory cell MCA and used for the fatigue test, as compared with other via-plugs 104B or 104B* by about 1.3 times, for example.

According to such a construction, it becomes possible to increase the effect of hydrogen to the circled ferroelectric memory cell of FIG. 14A used for the measurement from the via-plug 104B**, and thus, it becomes possible to deteriorate the fatigue characteristics with certainty. Thus, when the circled ferroelectric memory cell has passed the fatigue test, it is safely judged that the entire ferroelectric memory cells on that wafer would pass the fatigue test.

FIG. 14B is a plan view diagram representing a modification of the embodiment of FIG. 14A.

Referring to FIG. 14B, it can be seen that the via-plug 104B** closest to the circled ferroelectric memory cell MCA is formed closer to the real memory cell array 19_{REAL} as compared with other via-plug 104B or 104B*.

With such a construction, too, it becomes possible to increase the effect of hydrogen to the circled ferroelectric memory cell of FIG. 14B used for the measurement from the via-plug 104B**, and thus, it becomes possible to deteriorate the fatigue characteristics with certainty. Thus, when the circled ferroelectric memory cell has passed the fatigue test, it is safely judged that the entire ferroelectric memory cells on that wafer would pass the fatigue test.

It is preferable that the via-plug 104B** thus provided closer to the ferroelectric capacitor MCA used for the measurement of the fatigue characteristics is formed, at the time of the fabrication of the product semiconductor devices, in the outermost periphery of the real memory cell array of that chip region which is expected to show the severest degradation of fatigue characteristics from the in-plane distribution of the crystal orientation in the database.

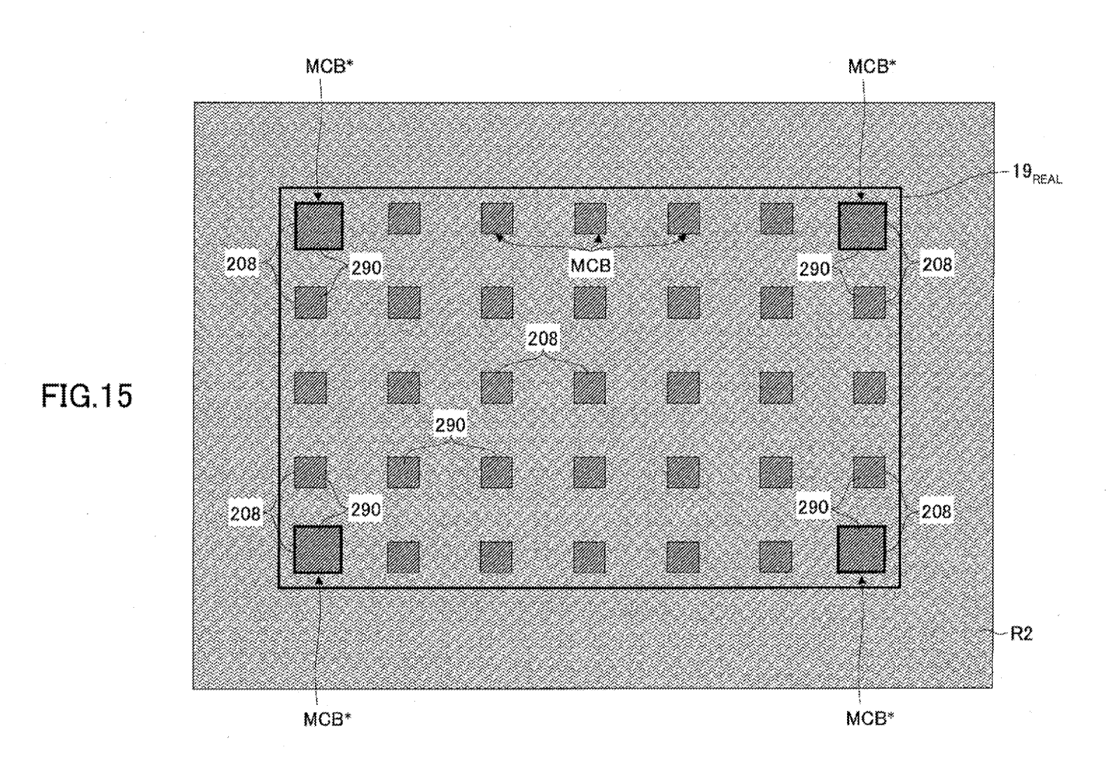

Likewise, it is possible to cause deterioration in the ferroelectric capacitors MCB* located at the outermost corners of the real memory cell array 19_{REAL} also in the stacked-type ferroelectric memory device by increasing the opening 208 by about 1.3 times as represented in FIG. 15.

Thus, when the ferroelectric capacitor having such degraded fatigue characteristics have passed the fatigue test, it is safely concluded that other ferroelectric capacitors on the same wafer have the fatigue characteristics that passes the fatigue test.

It is preferable that the ferroelectric capacitor MCB* thus having increased via-diameter is formed, at the time of the fabrication of the product semiconductor devices, in the outermost periphery of the real memory cell array 19_{REAL} of that chip region which is expected to show the severest degradation of fatigue characteristics from the in-plane distribution of the crystal orientation in the database.

While the foregoing embodiments have been explained of the case in which the ferroelectric film is formed by a sputtering process, it will be understood from the foregoing explanations that the foregoing explanations are valid also in the case the ferroelectric film is formed by other manufacturing process such as a sol-gel process or MOCVD process. In such cases, it is sufficient to read out the information relating to the process used from the fabrication of the product ferroelectric memory devices as one of the information read out from the database 41.

What is claimed is:

1. A method of producing semiconductor devices, comprising:
a first step of acquiring an in-plane distribution of fatigue characteristics for ferroelectric capacitors formed on a testing wafer; and
a second step of fabricating semiconductor devices having respective ferroelectric capacitors on a wafer as a product based on said in-plane distribution,
wherein said second step comprises:
forming said plurality of ferroelectric capacitors on said wafer on which said semiconductor devices are fabricated as a product;
designating a specific region of said wafer on which said semiconductor devices are fabricated as a product from said in-plane distribution of fatigue characteristics acquired in said first step;
measuring fatigue characteristics of a ferroelectric capacitor of a semiconductor device on said specific region;
judging said ferroelectric capacitor of said specific region as to good or fail based on said fatigue characteristics measured for said ferroelectric capacitor of said semiconductor device on said specific region; and
rendering that all of said plurality of ferroelectric capacitors are good on said wafer on which said semiconductor devices are fabricated as a product when a result of said judging is good.

2. The method as claimed in claim 1, wherein said ferroelectric capacitors on said testing wafer and said ferroelectric capacitors on said wafer on which said semiconductor devices are formed as a product contain a metal element that causes hydrogen to perform a catalytic action in any of an upper electrode and a lower electrode.

3. The method as claimed in claim 1, wherein said acquiring of in-plane distribution is attained by measuring a distribution of crystal quality of a ferroelectric film formed on said testing wafer in said first step.

4. The method as claimed in claim 1, wherein said acquiring of in-plane distribution is attained by measuring a distribution of crystal orientation of a ferroelectric film formed on said testing wafer in said first step.

5. The method as claimed in claim 1, wherein said ferroelectric capacitors formed on said testing wafer and said ferroelectric capacitors formed on said wafer on which said semiconductor devices are fabricated as a product contain a PZT film as a ferroelectric film, and wherein said specific region is designated, based on said in-plane distribution, as a region having a proportion of a (111) orientation or (222) orientation of 90% or less.

6. The method as claimed in claim 1, wherein said second step is conducted consecutively for a plurality of wafers on which said semiconductor devices are fabricated as a product.

7. The method as claimed in claim 1, wherein there are defined a plurality of chip regions on said wafer on which the semiconductor devices are fabricated as product, said plurality of capacitors forming an array in each of said plurality of chip regions, said array including an array of operable ferroelectric capacitors and inoperable ferroelectric capacitors surrounding said array of operable ferroelectric capacitors, wherein said ferroelectric capacitor used for said judging is selected from said array of said operable ferroelectric capacitors included in said specific region.

8. The method as claimed in claim 7, wherein said judging in said second step is conducted by using a ferroelectric capacitor closest to a source of hydrogen from said array of said operable ferroelectric capacitors.

9. The method as set forth in claim 7, wherein said judging in said second step is conducted by using a ferroelectric capacitor included in an outermost periphery of said array of said operable ferroelectric capacitors.

10. The method as claimed in claim 7, wherein said ferroelectric capacitor used for judging in said second step is selected from outermost corners of said array of said real capacitors.

11. The method as claimed in claim 7, wherein, in each of said chip regions, said ferroelectric capacitor has a planar construction in which a plurality of ferroelectric capacitors in said array share a common bottom electrode and an interconnection pattern is connected electrically to an end of said lower electrode via a via-plug, and wherein said ferroelectric capacitor used for said judging is a ferroelectric capacitor located closest to said via-plug.

12. The method as claimed in claim 8, wherein, in each of said chip regions, said ferroelectric capacitor has a stacked construction in which a plurality of ferroelectric capacitors in said array have respective lower electrodes of Pt and said lower electrodes have respective via-plugs connected thereto electrically.

13. A semiconductor device, comprising:
a transistor formed on a substrate;
a plurality of ferroelectric capacitors of a planar structure formed over said transistors, said plurality of ferroelectric capacitors forming a plurality of arrays each including a common lower electrode and a plurality of upper electrodes formed over said common lower electrode; and
a via-plug connected to each of said lower electrodes,
wherein at least one via-plug has a size larger than other via-plugs.

14. A semiconductor device, comprising:
a transistor formed on a substrate;
a plurality of ferroelectric capacitors of a planar structure formed over said transistor, said plurality of ferroelectric capacitors forming a plurality of arrays each including a common lower electrode and a plurality of upper electrodes formed over said common lower electrode; and
a via-plug connected to each of said lower electrodes,
wherein, in at least one array, a distance between a via-plug and a nearest neighboring ferroelectric capacitor on the same lower electrode is nearer than a distance between a via-plug and a nearest neighboring ferroelectric capacitor of another array.

15. The semiconductor device as claimed in claim 13, wherein said lower electrode comprises Pt.

16. A semiconductor device as claimed in claim 13, wherein said plurality of ferroelectric capacitors comprise operable ferroelectric capacitors and unused ferroelectric capacitors, and wherein said ferroelectric capacitors formed on said common lower electrode to which a via-plug is formed with a size larger than other via-plugs comprise operable ferroelectric capacitors.
